(19) United States
(12) Patent Application Publication
(10) Pub. No.: US 2022/0399879 A1
(43) Pub. Date: Dec. 15, 2022

(54) SYNCHRONOUS SWITCH CONTROL METHOD

(71) Applicant: TEXAS INSTRUMENTS INCORPORATED, Dallas, TX (US)

(72) Inventors: Tong Yao, San Jose, CA (US); Johan Tjeerd Strydom, Saratoga, CA (US)

(73) Assignee: TEXAS INSTRUMENTS INCORPORATED, Dallas, TX (US)

(21) Appl. No.: 17/513,505

(22) Filed: Oct. 28, 2021

Related U.S. Application Data
(60) Provisional application No. 63/209,534, filed on Jun. 11, 2021.

(51) Int. Cl. H03K 3/017; H02M 1/08

(52) U.S. Cl. CPC H03K 3/017; H02M 1/08; H02M 3/335

(57) ABSTRACT

A method includes generating a PWM signal having a first edge to turn a transistor on and a second edge to turn the transistor off in respective switching cycles; determining a target turn on point and a target turn off point based on a measured electrical signal of the transistor responsive to the PWM signal of a switching cycle of a present control cycle; and adjusting the first edge and/or the second edge of the PWM signal for a switching cycle of a subsequent control cycle based on the determined target turn on point and/or the determined target turn off point.

### CROSS-REFERENCE TO RELATED APPLICATION

This application claims priority to and benefit of U.S. Provisional Patent Application Ser. No. 63/209,534, filed on Jun. 11, 2021, and titled “SYNCHRONOUS SWITCH CONTROL METHOD”, the contents of which are hereby fully incorporated by reference.

### BACKGROUND

Switching power conversion systems use transistors to convert power from one form to another, such as for DC to DC, DC to AC, and AC to DC applications. High efficiency is important in many applications and can be improved by reducing switching losses in the transistors. Increasing the transistor switching frequency can improve the converter power density. Silicon carbide (SiC), gallium nitride (GaN) and other high electron mobility transistors (HEMTs) offer improved performance and reduced switching loss at higher frequencies. However, third quadrant conduction losses can occur when operating in the third quadrant of a current-voltage graph when the drain-source voltage of the transistor is negative. Third quadrant conduction loss can be significant in certain power converters, such as synchronous rectifiers. In a synchronous rectifier, the GaN and other HEMT transistors can suffer from high third quadrant conduction loss. Moreover, the loss becomes significant at higher frequency operation. Controlling the relative switching times for transistors on the primary and secondary side of an isolation transformer is difficult because the secondary side switches are controlled via a signal channel with isolation circuitry having propagation delays, and the on time and phase relative to the primary side transistors is unknown and can vary. Control response to measurement at the secondary circuitry is delayed by sensor, logic and gate driver delays. For example, secondary side converter voltage and current signals are transferred through isolation circuits and converted for digital processing, and responsive switching control signals are transferred through a digital isolator to operate the switching transistor. Overcoming these delays can help reduce power loss in a switching converter.

### SUMMARY

In one aspect, a method includes generating a pulse width modulated (PWM) signal having a first edge to turn a transistor on and a second edge to turn the transistor off in respective switching cycles of a power conversion system. The method further includes determining target turn on and turn off points based on a measured electrical signal of the transistor responsive to the PWM signal of a switching cycle of a present control cycle. The method also includes adjusting the first and/or second edges of the PWM signal for a switching cycle of a subsequent control cycle based on the determined target turn on and/or turn off points for a switching cycle of a subsequent control cycle.

In another aspect, a non-transitory computer readable medium stores computer executable instructions, which, when executed by a processor, cause the processor to: generate a PWM signal having a first edge to turn a transistor on and a second edge to turn the transistor off in respective switching cycles of a power conversion system; determine target turn on and turn off points based on a measured electrical signal of the transistor responsive to the PWM signal of a switching cycle of a present control cycle; and adjust the first and/or second edges of the PWM signal for a switching cycle of a subsequent control cycle based on the determined target turn on and/or turn off points for a switching cycle of a subsequent control cycle.

In another aspect, a system includes a transistor and a controller. The controller is configured to: generate a PWM signal having a first edge to turn a transistor on and a second edge to turn the transistor off in respective switching cycles of a power conversion system; determine target turn on and turn off points based on a measured electrical signal of the transistor responsive to the PWM signal of a switching cycle of a present control cycle; and adjust the first and/or second edges of the PWM signal for a switching cycle of a subsequent control cycle based on the determined target turn on and/or turn off points for a switching cycle of a subsequent control cycle.

In another aspect, an electronic device includes a first input, a second input, an output, and a pulse generator. The first input is adapted to be coupled to a source of a transistor and the second input is adapted to be coupled to a drain of the transistor. The pulse generator is configured to generate a pulse signal at the output responsive to a measured electrical signal of the transistor indicating third quadrant conduction of the transistor.

### BRIEF DESCRIPTION OF THE DRAWINGS

FIG. 1 is a schematic diagram of a power conversion system with pulse timing adjustment by a controller to mitigate third quadrant conduction of switching transistors using timing information from a pulse generator integrated with a transistor in a half bridge secondary circuit.

FIG. 1A is a schematic diagram of an example pulse generator.

FIG. 1B is a schematic diagram of another example pulse generator.

FIG. 1C is a schematic diagram of another example pulse generator.

FIG. 1D is a schematic diagram of another example pulse generator.

FIG. 1E is a schematic diagram of another example pulse generator.

FIG. 1F is a flow diagram of a pulse timing adjustment control method of the controller of FIG. 1.

FIG. 2 is a flow diagram of another example pulse timing adjustment control method.

FIG. 3A is a signal diagram of switching signals in a present control cycle.

FIG. 3B is a signal diagram of switching signals in a subsequent control cycle.

FIG. 4 is a schematic diagram of another example pulse timing adjustment control method.

FIG. 5A is a signal diagram showing example switching rectifier turn on and conduction length signals.

FIG. 5B is a signal diagram showing example switching rectifier turn on and turn off signals.

FIG. 6A is a signal diagram of drain-source voltage, gate-source voltage and pulse generator signals in a present control cycle using turn on edge control.

FIG. 6B is a signal diagram of drain-source voltage, gate-source voltage and pulse generator signals in a subsequent control cycle using turn on edge control.

FIG. 7A is a signal diagram of transistor current, gate-source voltage and pulse generator signals in a present control cycle using turn off edge control.

FIG. 7B is a signal diagram of transistor current, gate-source voltage and pulse generator signals in a subsequent control cycle using turn off edge control.

FIG. 8 is a signal diagram of carrier signals and pulse generator signals for turn on and turn off edge control.

FIG. 9A is a signal diagram of simulated power converter signals with phase shift.

FIG. 9B is a signal diagram of simulated power converter signals without phase shift.

FIG. 10A is a signal diagram of simulated power converter signals where an estimated delay equals a real delay.

FIG. 10B is a signal diagram of simulated power converter signals where an estimated delay is less than a real delay.

FIG. 10C is a signal diagram of simulated power converter signals where an estimated delay is greater than a real delay.

FIG. 11A is a signal diagram of transistor current, gate-source voltage and pulse generator signals in a present control cycle using pulse length control.

FIG. 11B is a signal diagram of transistor current, gate-source voltage and pulse generator signals in a subsequent control cycle using pulse length edge control.

FIG. 12 is a schematic diagram of a power conversion system with pulse timing adjustment by a controller to mitigate third quadrant conduction of switching transistors using timing information from an external pulse generator in a half bridge secondary circuit.

FIG. 13 is a schematic diagram of a power conversion system with pulse timing adjustment by a controller to mitigate third quadrant conduction of switching transistors using timing information from a pulse generator in a half bridge secondary circuit.

FIG. 14 is a schematic diagram of a power conversion system with pulse timing adjustment by a controller to mitigate third quadrant conduction of switching transistors using timing information from pulse generators at two corners of a full bridge secondary circuit.

FIG. 15 is a schematic diagram of a power conversion system with pulse timing adjustment by a controller to mitigate third quadrant conduction of switching transistors using timing information from pulse generators at four corners of a full bridge secondary circuit.

FIG. 16 is a schematic diagram of a power conversion system with pulse timing adjustment by a controller to mitigate third quadrant conduction of switching transistors using timing information from a single output pulse generator integrated with a transistor in a half bridge secondary circuit.

FIG. 16A is a schematic diagram of the single output pulse generator in the power conversion system of FIG. 16.

FIG. 16B is a signal diagram of the output signal having a first pulse pattern of the single output pulse generator of FIG. 16A in a present control cycle.

FIG. 16C is a signal diagram of the output signal having a second pulse pattern of the single output pulse generator of FIG. 16A in a present control cycle.

FIG. 16D is a signal diagram of the first and second pulse patterns of the single output pulse generator of FIG. 16A.

FIG. 16E is a signal diagram of an output signal having another example second pulse pattern of another single output pulse generator in a present control cycle.

FIG. 17 is a schematic diagram of a power conversion system with pulse timing adjustment by a controller to mitigate third quadrant conduction of switching transistors using timing information from an external pulse generator of FIG. 16A in a half bridge secondary circuit.

FIG. 18 is a schematic diagram of a power conversion system with pulse timing adjustment by a controller to mitigate third quadrant conduction of switching transistors using timing information from the pulse generators of FIG. 16A at four corners of a full bridge secondary circuit.

FIG. 19 is a schematic diagram of a power conversion system with pulse timing adjustment by a controller to mitigate third quadrant conduction of switching transistors using timing information from the pulse generators of FIG. 16A at two corners of a full bridge secondary circuit.

FIG. 20 is a flow diagram of pulse timing adjustment in the controller using the pulse signal from the pulse generator of FIG. 16A.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

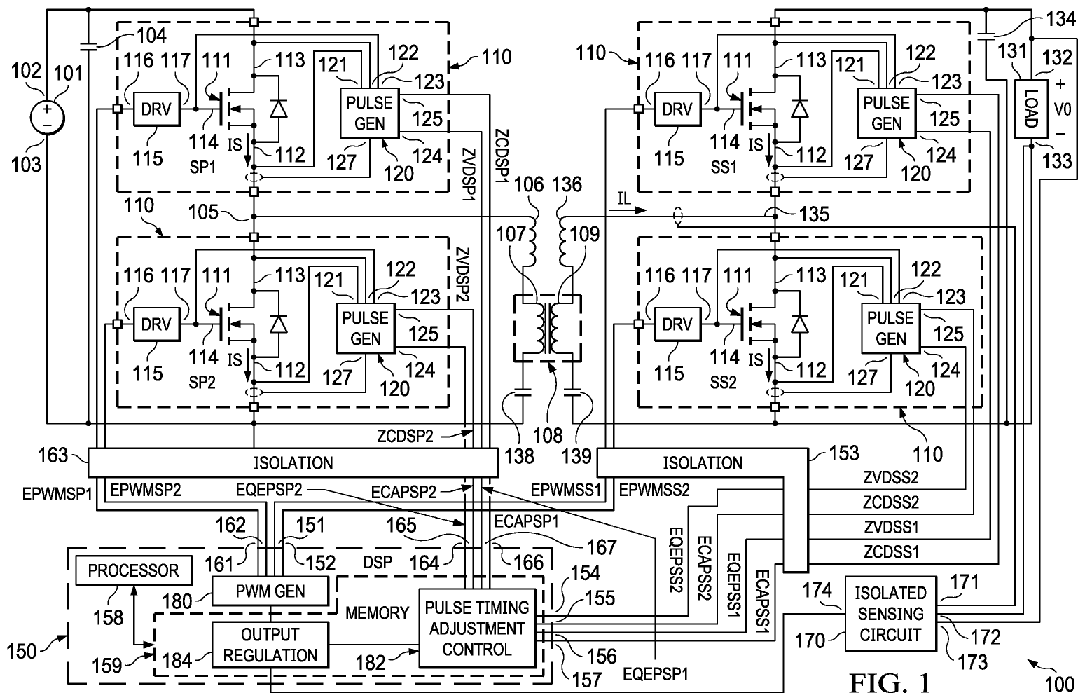

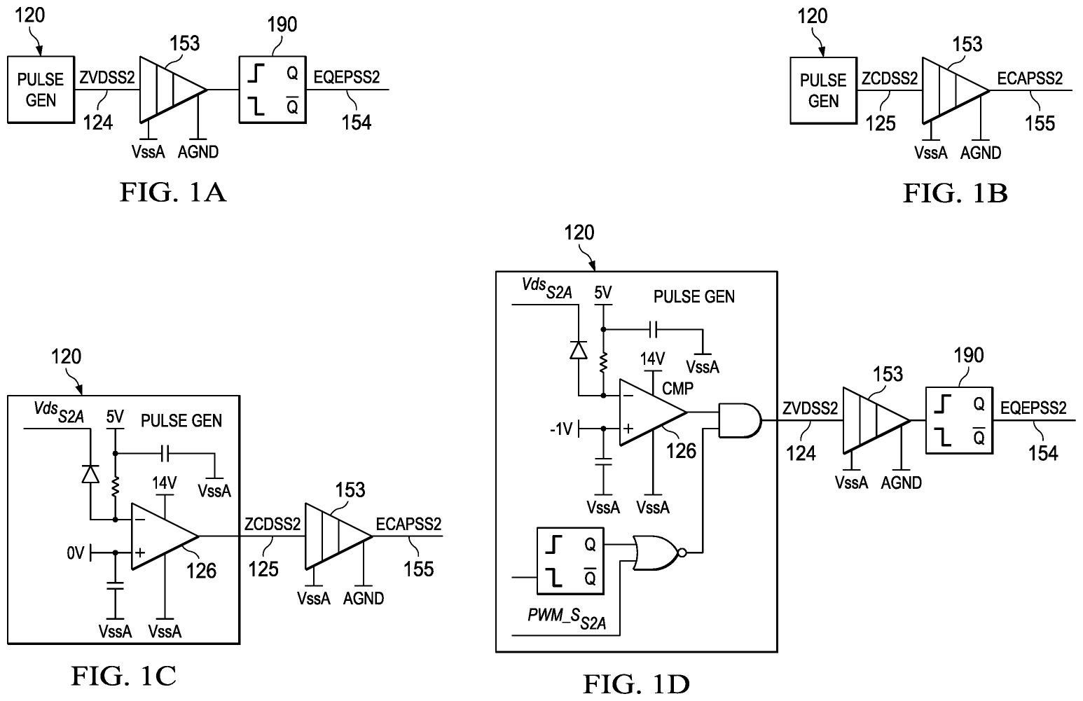

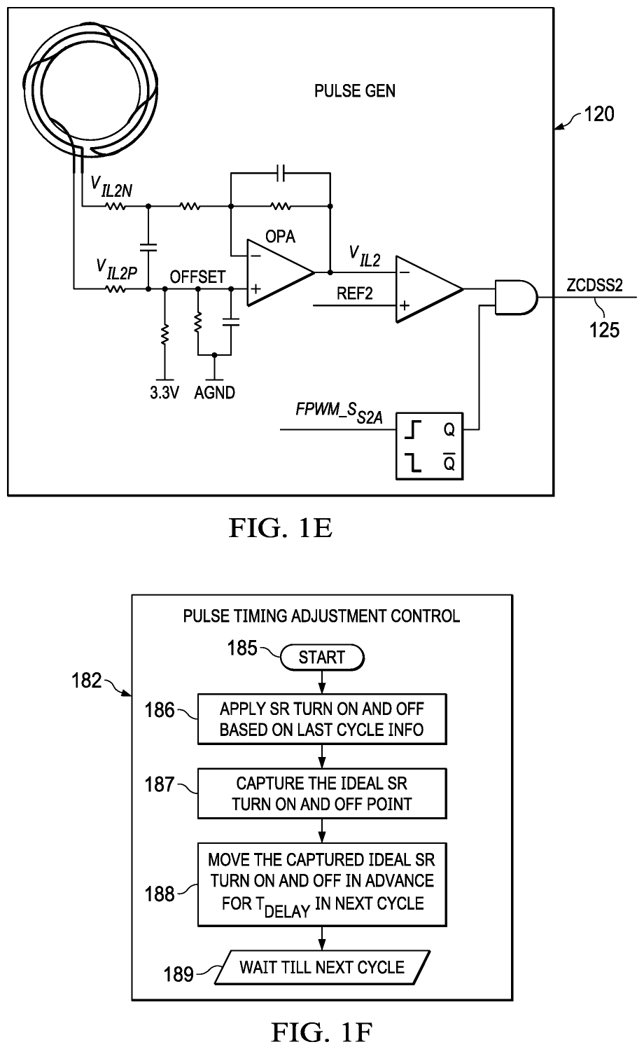

FIG. 1 shows a power conversion system 100 that includes an isolation transformer 108 coupling primary and secondary switching circuits with integrated driver/transistor devices 110 connected in half-bridge configurations. The systems converts DC input power from a source or supply 101 to provide a regulated DC output voltage signal VO to a load 131. The system 100 has a synchronous rectifier secondary side circuit. The disclosed apparatus and methods are applicable to other forms and types of switching converters in other implementations. The system 100 has a controller 150, such as a digital signal processor (DSP) that implements pulse timing adjustment to mitigate third quadrant conduction of switching transistors using timing information from a pulse generator 120 integrated with a transistor.

The input power source 101 has a first terminal 102 and a second terminal 103. An input capacitor is coupled between the first and second terminals 102 and 103 of the power source 101. The primary side half-bridge circuit includes upper and lower primary side transistors 111, such as GaN, SiC or other type of transistors coupled in series with one another between the first and second terminals 102 and 103 of the power source 101. The primary side transistors 111 are coupled to one another at a primary side switching node 105. An inductor 106 has a first terminal coupled to a first terminal of a primary winding 107 of the transformer 108. A second terminal of the primary winding 107 is coupled by a capacitor 138 to the second terminal 103 of the input power source 101. The isolation transformer 108 has a secondary winding 109 coupled by a secondary side inductor 136 to a secondary side switching node 135. The secondary circuit has upper and lower secondary side transistors 111 are coupled to one another at the secondary side switching node 135.

The transistors 111 in this example are integrated with driver and pulse generator circuitry in respective electronic devices 110, such as integrated circuits. The upper integrated driver/transistor device 110 of the primary circuit is labeled “SP1” and the lower integrated driver/transistor device 110 of the primary circuit is labeled “SP2”. The upper integrated driver/transistor device 110 of the secondary circuit is labeled “SS1” and the lower integrated driver/transistor device 110 of the secondary circuit is labeled “SS2”. The respective integrated driver/transistor devices 110 include a respective transistor 111, a driver 115 (e.g., labeled “DRV” in the drawings), and a pulse generator 120 (e.g., labeled “PULSE GEN” in the drawings). The transistor 111 has a source 112, a drain 113, and a gate 114. The driver 115 has an input 116 and an output 117, and is a circuit having electronic components such as transistors, resistors, capacitors, amplifiers, etc., that are configured to implement gate driver functions to control the switching of the transistor 111. The driver 115 provides a gate drive signal at the output 117 based on a pulse width modulated pulse signal received at the input 116 to control the gate 114 of the transistor 111 and to turn the transistor 111 on and off in a controlled fashion. When the transistor 111 is turned on (e.g., by a high gate control signal from the driver 115) with a non-zero drain-source voltage present, a current IS flows at (e.g., into or out of) the source terminal.

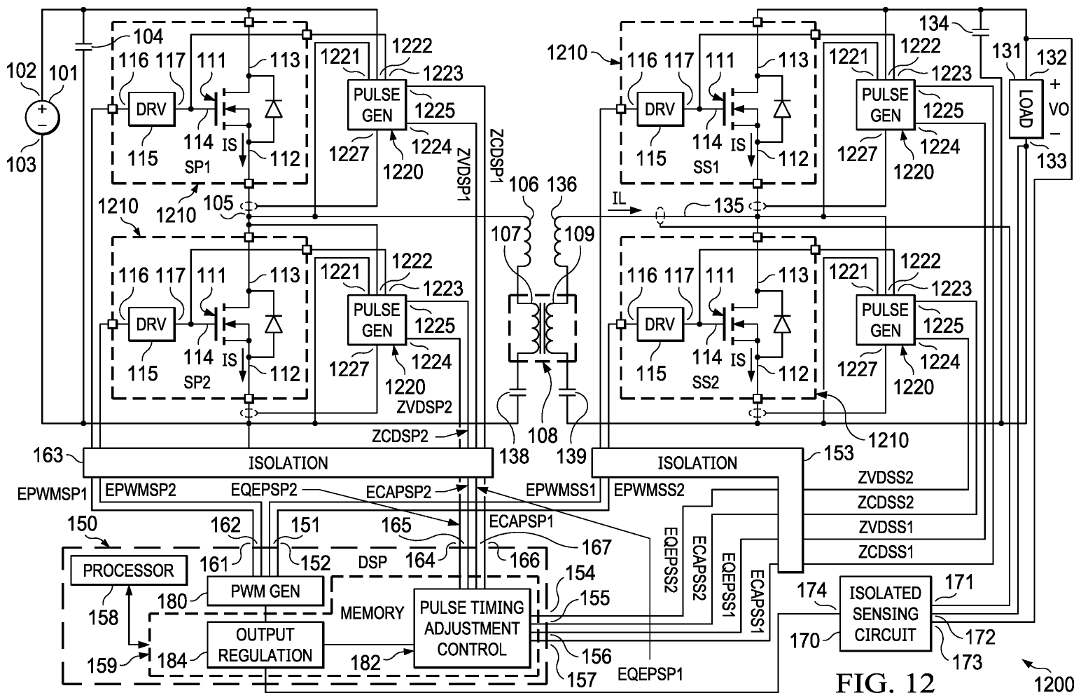

The individual integrated driver/transistor devices 110 include the pulse generator 120. The pulse generator 120 has a first input 121, a second input 122, a third input 123, a first output 124, a second output 125, and a current sense input 127. The first input 121 is coupled to the source 112 of the transistor 111. The second input 122 is coupled to the drain 113 of the transistor 111. The third input 123 is coupled to the gate 114 of the transistor 111. The current sense input 127 senses the source current IS of the transistor 111. The pulse generator 120 is a circuit having electronic components such as transistors, resistors, capacitors, amplifiers, etc., that are configured to generate one or more pulse signals at the respective outputs 124 and 125. In another example, the pulse generator 120 is not integrated with the transistor 111 or the driver 115, as described further below in connection with FIG. 12. The respective pulse generators 120 of the circuit associated with the secondary side of the transformer 108 in one example are each configured to generate a first pulse signal at the respective first output 124, and to generate a second pulse signal at the respective second output 125. The respective first pulse signals of the circuit associated with the secondary side of the transformer 108 are labeled ZVDSS1 and ZVDSS2 in FIG. 1. The respective second pulse signals of the circuit associated with the secondary side of the transformer 108 are labeled ZCDSS1 and ZCDSS2 in FIG. 1. The respective pulse generators 120 of the circuit associated with the primary side of the transformer 108 in one example are each configured to generate a first pulse signal at the respective first output 124, and to generate a second pulse signal at the respective second output 125. The respective first pulse signals of the circuit associated with the primary side of the transformer 108 are labeled ZVDSP1 and ZVDSP2 in FIG. 1. The respective second pulse signals of the circuit associated with the primary side of the transformer 108 are labeled ZCDSP1 and ZCDSP2 in FIG. 1.

The load 131 has a first terminal 132 and a second terminal 133. The load terminals 132 and 133 are coupled to the secondary circuit. A first terminal of the secondary winding 109 is coupled to a first terminal of the inductor 136. A second terminal of the inductor 136 is coupled to the secondary side switching node 135. A second terminal of the secondary winding 109 is coupled to a first terminal of a capacitor 139. A second terminal of the capacitor 139 is coupled to the second terminal 133 of the load 131. The upper and lower secondary side transistors 111 are coupled to one another at the secondary side switching node 135. An output capacitor 134 has a first terminal coupled to the first terminal 132 of the load 131. A second terminal of the output capacitor 134 is coupled to the second terminal 133 of the load 131.

The controller 150 in one example is a DSP having inputs for digital signals and outputs for generated output signals. The controller 150 has outputs 151, 152, and inputs 154, 155, 156, and 157 for interfacing with the secondary side circuitry of the system 100 via an isolation circuit 153. The isolation circuit 153 is a circuit having electronic components such as transistors, resistors, capacitors, amplifiers, etc., that are configured to transfer signals through an isolation barrier between the controller 150 and the secondary circuitry of the system 100. The isolation circuit 153 of the secondary side of the transformer 108 receives the first pulse signals ZVDSS1 and ZVDSS2 and the second pulse signals ZCDSS1 and ZCDSS2 from the respective pulse generators 120 of the circuitry associated with the secondary side of the transformer 108. The isolation circuit 153 is configured to generate isolated first pulse signals EQEPSS1 and EQEPSS2 that correspond to the respective first pulse signals ZVDSS1 and ZVDSS2 of the circuitry associated with the secondary side of the transformer 108. The isolation circuit 153 is configured to generate isolated second pulse signals ECAPSS1 and ECAPSS2 that correspond to the respective second pulse signals ZCDSS1 and ZCDSS2 of the circuitry associated with the secondary side of the transformer 108. The first pulse signals ZVDSS1 and ZVDSS2 and the respective isolated first pulse signals EQEPSS1 and EQEPSS2 are referred to herein as first pulse signals. The second pulse signals ZCDSS1 and ZCDSS2 and the respective isolated second pulse signals ECAPSS1 and ECAPSS2 are referred to herein as second pulse signals.

The controller 150 includes a processor 158 operatively coupled to an electronic memory 159. The memory 159 provides a non-transitory computer readable medium 159 that stores computer executable instructions, which, when executed by the processor 158, cause the processor 158 to implement the functions described herein, including output voltage regulation by generating PWM signals to operate the transistors 111 of the primary and secondary side circuits of the system 100.

The controller 150 also has outputs 161, 162, and inputs 164, 165, 166, and 167 for interfacing with the primary side circuitry of the system 100 via an isolation circuit 163. The isolation circuit 163 is a circuit having electronic components such as transistors, resistors, capacitors, amplifiers, etc., that are configured to transfer signals through an isolation barrier between the controller 150 and the primary circuitry of the system 100. The respective pulse generators 120 of the circuit associated with the primary side of the transformer 108 in one example are each configured to generate a first pulse signal at the respective first output 124, and to generate a second pulse signal at the respective second output 125. The isolation circuit 163 of the primary side of the transformer 108 receives the first pulse signals ZVDSP1 and ZVDSP2 and the second pulse signals ZCDSP1 and ZCDSP2 from the respective pulse generators 120 of the circuitry associated with the primary side of the transformer 108. The isolation circuit 163 is configured to generate isolated first pulse signals EQEPSP1 and EQEPSP2 that correspond to the respective first pulse signals ZVDSP1 and ZVDSP2 of the circuitry associated with the primary side of the transformer 108. The isolation circuit 153 is configured to generate isolated second pulse signals ECAPSP1 and ECAPSP2 that correspond to the respective second pulse signals ZCDSP1 and ZCDSP2 of the circuitry associated with the primary side of the transformer 108. The first pulse signals ZVDSP1 and ZVDSP2 and the respective isolated first pulse signals EQEPSP1 and EQEPSP2 are referred to herein as first pulse signals. The second pulse signals ZCDSP1 and ZCDSP2 and the respective isolated second pulse signals ECAPSP1 and ECAPSP2 are referred to herein as second pulse signals.

The system 100 also includes an isolated output sensing circuit 170 having inputs 171, 172, and 173, and an output 174. The input 171 is coupled to a current sensor to sense an inductor current IL of the secondary side inductor 136. The inputs 172 and 173 are coupled to the respective load terminals 132 and 133 to sense the output voltage VO of the load 131. The output 174 is coupled to an input of the controller 150. The isolated output sensing circuit 170 is a circuit having electronic components such as transistors, resistors, capacitors, amplifiers, etc., that are configured to provide output feedback signals (e.g., analog signals, digital signals, etc.) that represent one or more electrical conditions of the secondary circuitry, such as the output voltage VO, the inductor current IL, etc.

The controller 150 includes a PWM generation circuit 180. The memory 159 stores output regulation instructions 184 and pulse timing adjustment control instructions 182 implemented by the processor 158 to control the switching states (e.g., on or off) of the primary and secondary side transistors 111 to convert input DC power from the source 101 to DC output power delivered to the load 131. The transformer 108 provides an isolation barrier that electrically isolates the input power and the primary side circuitry from the output power and the secondary side circuitry. The controller 150 is configured to generate PWM signals EPWMSP1 and EPWMSP2 at the respective outputs 161 and 162 to operate (e.g., turn on and turn off) the primary side transistors 111. The controller 150 is also configured to generate PWM signals EPWMSS1 and EPWMSS2 at the respective outputs 151 and 152 to operate (e.g., turn on and turn off) the secondary side transistors 111.

The controller 150 is configured by executing the instructions 184 to generate the PWM signals EPWMSP1, EPWMSP2, EPWMSS1, and EPWMSS2 in a closed loop control scheme to regulate the output voltage VO according to feedback signals received from the isolated output sensing circuit 170. The isolation circuit 163 transfers signals through the isolation barrier between the controller 150 and the primary circuitry of the system 100 to deliver PWM signals to the upper and lower primary side gate drivers 115 according to the respective PWM signals EPWMSP1 and EPWMSP2. The isolation circuit 153 transfers signals through the isolation barrier between the controller 150 and the secondary circuitry of the system 100 to deliver PWM signals to the upper and lower secondary side gate drivers 115 according to the respective PWM signals EPWMSS1 and EPWMSS2.

In the illustrated synchronous rectifier example, while powered and operating, the processor 158 executes the output regulation instructions 184 in a continuous series of control cycles to implement closed loop output regulation. In one example, each individual control cycle includes multiple switching cycles. In one example, each of the primary and secondary side transistors is turned on and turned off in each switching cycle. In one example, the controller 150 controls the PWM signal generation to transfer power from the primary side circuitry to the secondary side circuitry.

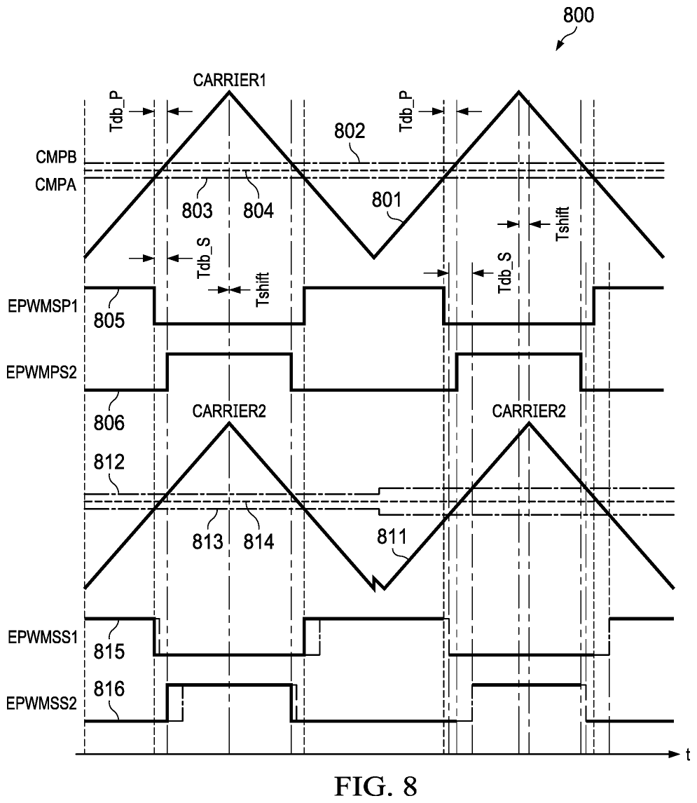

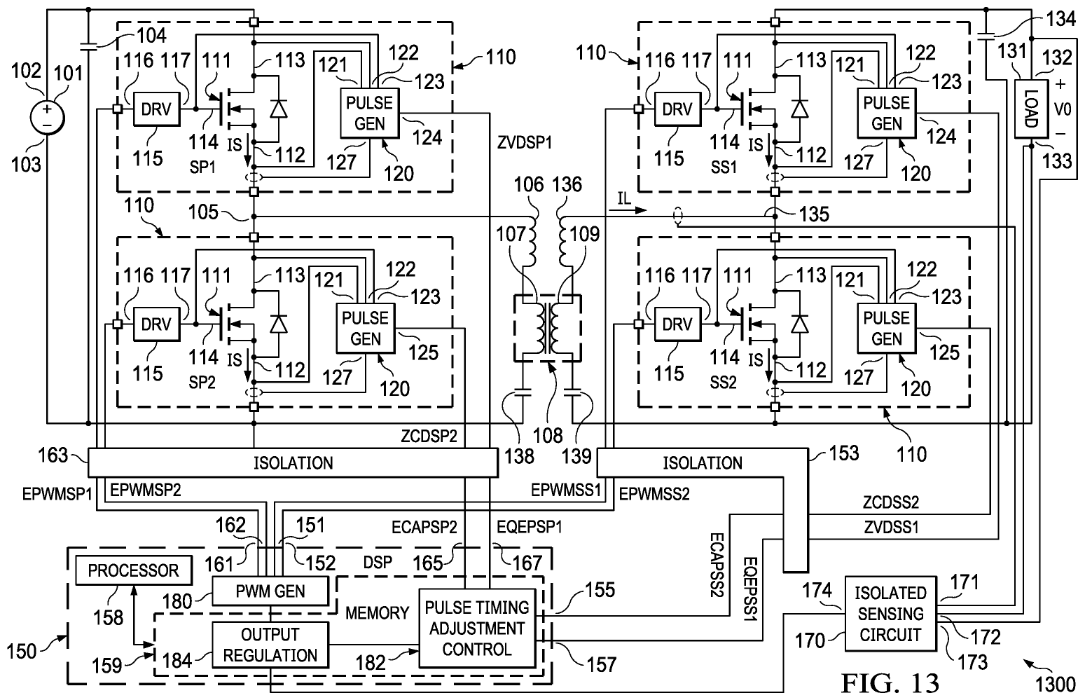

In one example, the individual switching cycles include a first mode, in which the controller 150 turns the upper primary and secondary side transistors 111 on and turns the lower primary and secondary side transistors off. In this example, the individual switching cycles also include a second mode, in which the controller 150 turns the upper primary and secondary side transistors 111 off and turns the lower primary and secondary side transistors on. FIGS. 8 and 13 below illustrate example switching cycles of the synchronous rectifier operation of the system 100, in which the controller 150 provides non-zero dead-band intervals to prevent both transistors 111 of the half bridge primary and secondary side circuits from being turned on concurrently.

The controller 150 is configured by executing the instructions 182 to selectively adjust the timing of one or more of the PWM signals EPWMSP1, EPWMSP2, EPWMSS1, and/or EPWMSS2 to help reduce third quadrant conduction of the associated transistors 111 and improve the efficiency of the power conversion system 100. In the illustrated example, the controller 150 receives information in the form of the isolated first pulse signals EQEPSP1, EQEPSP2, EQEPSS1, and EQEPSS2 via the respective isolation circuits 153 and 163 from the first outputs 124 of the respective pulse generators 120, as well as the isolated second pulse signals ECAPSP1, ECAPSP2, ECAPSS1, and ECAPSS2 via the respective isolation circuits 153 and 163 from the second outputs 125 of the respective pulse generators 120.

The operation of the pulse generators 120 and the pulse timing and control operation of the controller 150 are described in connection with the lower secondary side transistor 111, the associated PWM signal EPWMSS2 and the pulse signals EQEPSS2 and ECAPSS2 of the associated pulse generator 120. In the illustrated example, the controller 150 and the associated pulse generators 120 implement similar functions with respect to the upper transistors 111 and for the lower primary side transistor 111, the details of which are omitted for brevity.

Referring also to FIGS. 1A-1F, FIGS. 1A-1D show example internal implementations of the pulse generator 120 and associated external hardware implementations for generating the respective first and second pulse signals ZVDSS2 and ZCDSS2 and the respective first and second isolated pulse signals EQEPSS2 and ECAPSS2 via the isolation circuit 153 of the circuit associated with the secondary side of the transformer 108. In FIG. 1A, the pulse generator 120 of the integrated driver/transistor electronic device 110 internally generates a zero-voltage detection signal ZVD at the first output 124, and the isolation circuit 153 provides a corresponding signal to the input of an edge detector 190. The edge detector output is coupled to the controller input 154. The edge detector 190 is configured to provide a pulse EQEPSS2 at the edge detector output and to the controller input 154 in response to a rising edge of the zero-voltage detection signal ZVD via the isolation circuit 153.

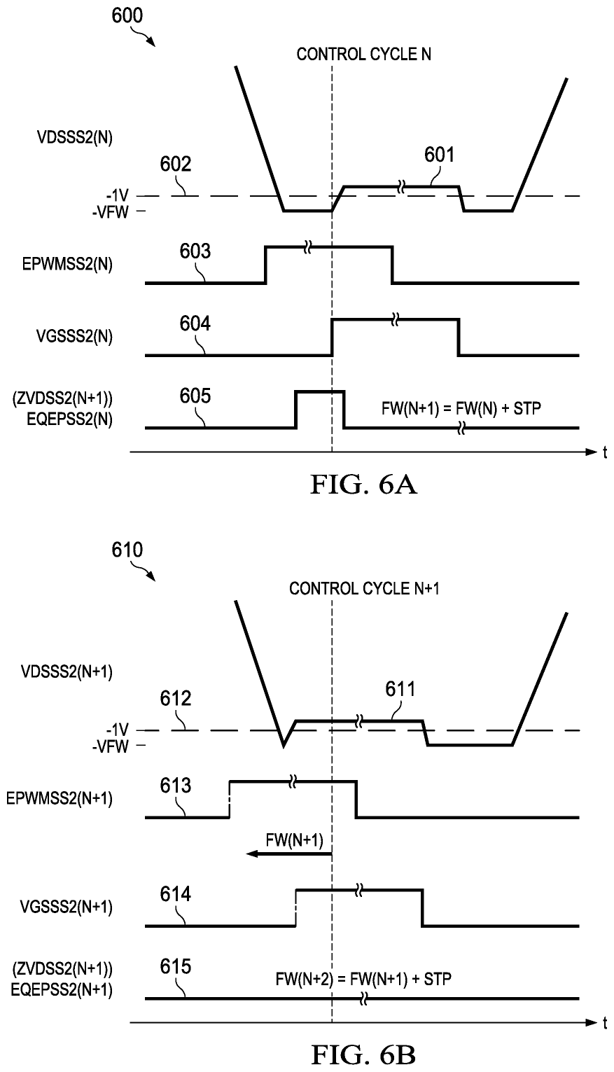

In one implementation, discussed further below in connection with FIGS. 6A and 6B, the pulse generator 120 in FIG. 1A generates the pulse signal EQEPSS2 with two edges in a given switching cycle where the associated transistor undergoes third quadrant conduction based on the sensed transistor drain-source voltage VDS, and generates the pulse signal EQEPSS2 with no edges in the given switching cycle where the associated transistor undergoes no detected third quadrant conduction before device turn-on based on the sensed transistor drain-source voltage VDS. The controller 150 in one example uses the first pulse signal EQEPSS2 to set or determine a target turn on point or to adjust a turn on time or point in switching cycles of a subsequent control cycle.

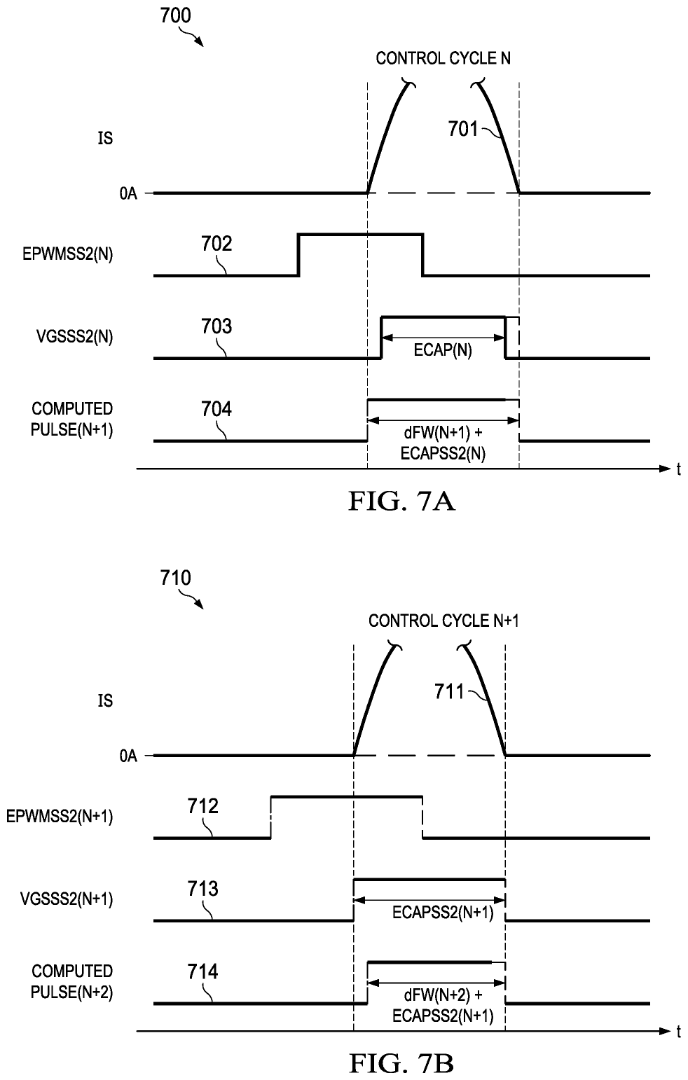

FIG. 1B shows another example pulse generator circuit implementation, in which the pulse generator 120 of the integrated driver/transistor electronic device 110 internally generates a zero current detection signal ZCD at the second output 125, and the isolation circuit 153 provides a corresponding second pulse signal ECAPSS2 to the input 155 of the controller 150. In this example, as described further below in connection with FIGS. 7A and 7B, the pulse generator 120 generates the second pulse signal ECAPSS2 having a pulse length in each switching cycle that corresponds to the actual duration of third quadrant current conduction by the associated transistor 111. The controller 150 in one example uses this pulse length of the second pulse signal ECAPSS2 to set or determine a target turn off point or to adjust a turn off time or point in switching cycles of a subsequent control cycle. In one implementation, the controller 150 uses an internal counter to count the length of the pulse from pulse generator 120, and the resulting ECAP count is used in the next cycle to create the EPWMSS2 PWM signal.

FIG. 1C shows another example pulse generator circuit implementation, in which the pulse generator 120 includes internal circuitry to sense the drain-source voltage VDS of the transistor 111 through a blocking diode. A comparator 126 compares the voltage VDS to a threshold, such as 0 V, and provides zero current detection signal at the output 125. The isolation circuit 153 provides a corresponding second pulse signal ECAPSS2 to the input 155 of the controller 150.

FIG. 1D shows another example pulse generator circuit, in which the pulse generator 120 includes a comparator 126 that compares the sensed drain-source voltage VDS to a threshold (e.g., −1 V) and logic circuitry generates an output pulse signal at the output 125. In one implementation, discussed further below in connection with FIGS. 6A and 6B, the pulse generator 120 in FIG. 1D generates the pulse signal EQEPSS2 within a given switching cycle where the associated transistor undergoes third quadrant conduction before device turn-on based on the sensed transistor drain-source voltage VDS. The circuit in FIG. 1D generates the pulse signal EQEPSS2 with no edges in the given switching cycle where the associated transistor is turned on before third quadrant conduction starts based on the sensed transistor drain-source voltage VDS. The controller 150 in one example uses the first pulse signal EQEPSS2 to set or determine a target turn on point or to adjust a turn on time or point in switching cycles of a subsequent control cycle. In this example, the VDS sensing circuit monitors the transistor turn on edge according to gate signal PWM_Sₛ₂.

Alternative implementation: If there is a negative VDS, the gate is still low, and the pulse generator 120 generates the first pulse signal with first and second edges. The isolation circuit 153 provides a corresponding signal to the input of an edge detector 190. The edge detector output in this example is coupled to the controller input 154 to provide the pulse signal to the controller 150. The controller 150 determines if a pulse signal edge is received or not and if so, determines that the associated transistor 111 experienced third quadrant conduction. When the controller 150 does not receive a pulse edge, there is no third quadrant conduction. The sensing window control PWM_Ss2 can be either EPWM_Ss2A, or Vgss2A.

FIG. 1E shows another example pulse generator circuit. In this example, the pulse generator 120 senses the transistor source current IS, and an op-amp (labeled “OPA”) amplifies and integrate the voltage signal coupled through Rogowski Coil with an offset, and a comparator compares the resulting amplified signal with a reference voltage Ref2. An AND gate has a first input coupled to the comparator output, and a second input coupled to the output of a counter that counts an input pulse signal FPWM_S_{s2A}. In another example, the AND gate and the counter are omitted, and the comparator output is coupled to the second output 125 of the pulse generator 120. The controller 150 in this example uses current sensing to correct the turn off edge of the PWM signal EPWMSS2 in response to the ECAPSS2 signal at the input 155. The controller uses an internal counter to count the temporal length of the ECAPSS2 pulse signal from the point of turn on to generate a comparison event trigger and uses the pulse length for the next control cycle to create the EPWMSS2 signal.

FIG. 1F shows a flow diagram of one implementation of the pulse timing adjustment control instructions 182 in execution as a method by the processor 158. This software or firmware configures the controller 150 to start a present control cycle at 185. The processor 158 executes the instructions 182 to configure the controller 150 of FIG. 1. At 186, the controller 150 applies synchronous rectifier (SR) turn on and turn off points in generating the PWM signal EPWMSS2 based on timing information from a previous (e.g., last) control cycle. The present control cycle is designated “N”, the previous control cycle is designated cycle “N−1” and a subsequent (e.g., next) control cycle is designated “N+1” for ease of reference. During the present control cycle N, the controller captures target (e.g., desired) turn on and turn off points at 187 based on information about electrical parameters of the transistor responsive to the PWM signal EPWMSS2(N) applied in the present control cycle N. At 188, the controller 150 selectively adjusts (e.g., moves) the turn on and/or turn off points for use in generating the PWM signal EPWMSS2(N+1) based on the target turn on and turn off points. At 189, the controller 150 continues operation in the present control cycle and returns to 185 to begin the next cycle.

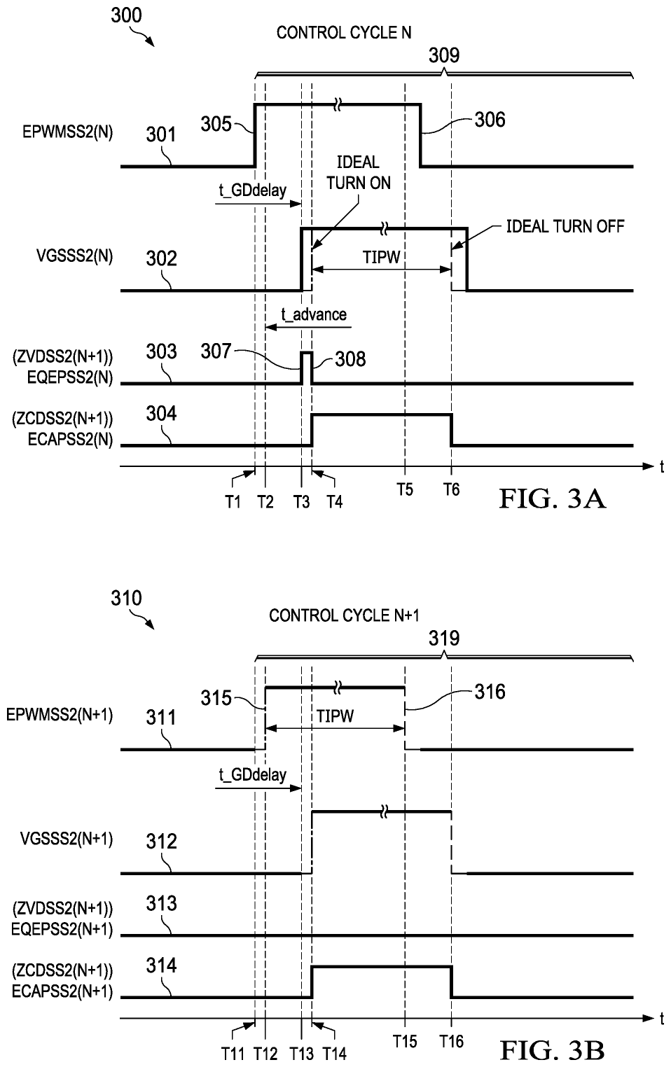

In operation for the example lower secondary side transistor 111, when powered, the firmware or software pulse timing adjustment control instructions 182 configure the controller 150 to generate the PWM signal EPWMSS2(N). As discussed further below in connection with FIGS. 3A and 3B, the PWM signal EPWMSS2(N) has a first edge (e.g., a rising edge) to turn the transistor 111 on, as well as a second edge (e.g., a falling edge) to turn the transistor 111 off in respective switching cycles. As mentioned, individual control cycles N−1, N, N+1 . . . include an integer number M switching cycles, where M is a positive integer, and the controller 150 generates and applies the PWM signal EPWMSS2 having first and second edges in each switching cycle, with adjustments made, as needed, in successive control cycles. The pulse timing adjustment control instructions 182 also configure the controller 150 to determine the target turn on point based on a measured electrical signal (e.g., a drain-source voltage VDS, a gate-source voltage VGS, a source current IS) of the transistor 111 responsive to the PWM signal EPWMSS2(N) of a switching cycle of the present control cycle N. The pulse timing adjustment control instructions 182 also configure the controller 150 to determine the target turn off point based on the measured electrical signal VDS, VGS, IS of the transistor 111 responsive to the PWM signal EPWMSS2(N) of the switching cycle of the present control cycle N. Based on the determined target turn on point, the controller 150 adjusts the first edge of the PWM signal EPWMSS2(N+1) for a switching cycle of a subsequent control cycle N+1. Based on the determined target turn off point, the controller 150 selectively adjusts the second edge of the PWM signal EPWMSS2(N+1) for the switching cycle of the subsequent control cycle N+1.

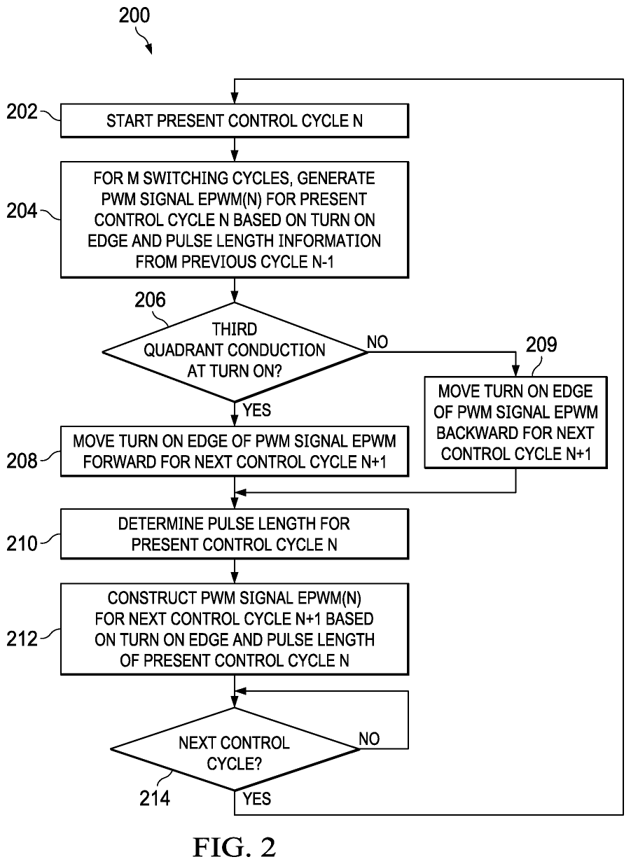

In one example, discussed further below in connection with FIG. 2, the controller 150 selectively moves the pulse start point forward or back ward in each successive control cycle, to mitigate third quadrant conduction of the transistor 111. In response to the determined target turn on point indicating third quadrant conduction of the transistor 111 in the switching cycle of the present control cycle N, the controller 150 adjusts the first edge of the PWM signal EPWMSS2(N+1) forward for the switching cycle or cycles of the subsequent control cycle N+1. In response to the determined target turn on point indicating no third quadrant conduction of the transistor 111 in the switching cycle of the present control cycle N, the controller 150 adjusts the first edge of the PWM signal EPWMSS2(N+1) backward for the switching cycle or cycles of the subsequent control cycle N+1.

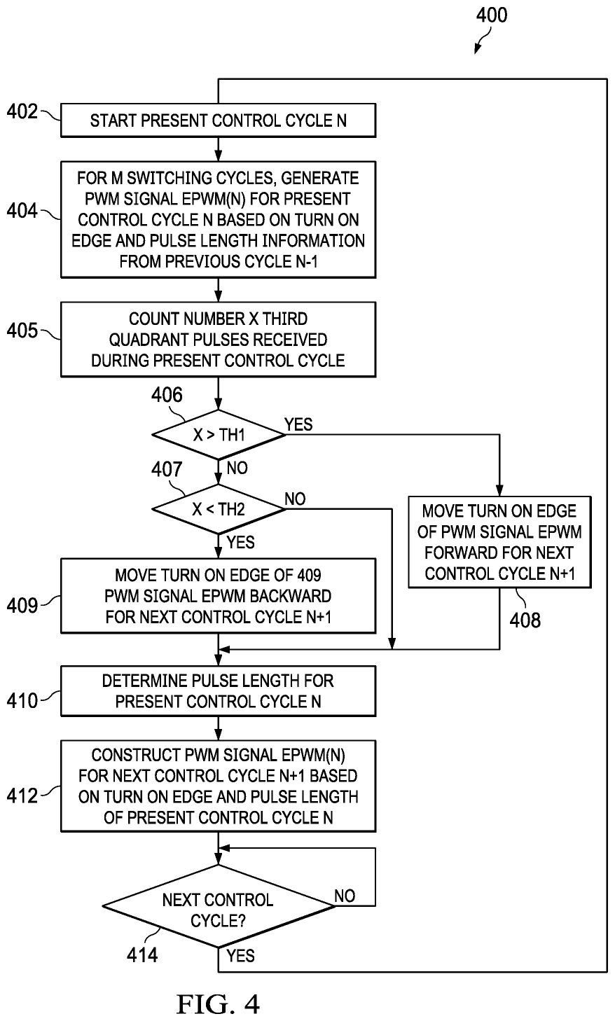

In another example, discussed further below in connection with FIG. 4, the controller 150 counts a number X of switching cycles for which the measured electrical signal indicates third quadrant conduction of the transistor 111 in the respective switching cycle, and compares the count X to upper and lower thresholds to selectively maintain the same PWM signal EPWMSS2(N+1) for a count value X between the thresholds, or adjust the PWM signal EPWMSS2(N+1) forward or backward for the next control cycle N+1.

Referring also to FIGS. 2, 3A, and 3B, FIG. 2 shows an example pulse timing adjustment control method 200 that adjusts the PWM signal EPWMSS2(N+1) forward or backward for successive control cycles based on the determined target turn on and turn off points. FIG. 3A shows a graph 300 of switching signals in a present control cycle N and FIG. 3B shows a graph 310 with switching signals in a subsequent control cycle N+1. The method 200 starts a present cycle N at 202 in FIG. 2. At 204, for the positive integer number M switching cycles of the present control cycle N, the controller 150 generates the PWM signal EPWMSS2(N) based on turn on edge and pulse length information from the previous control cycle N−1.

The graph 300 in FIG. 3A shows signal curves 301, 302, 303, and 304 in an example switching cycle 309 of the present switching cycle N. The graph 300 shows events at marked times T1, T2, T3, T4, T5, and T6 in the switching cycle 309. The curve 301 shows the PWM signal EPWMSS2(N) having a first edge 305 at time T1 to turn the transistor 111 on and a second edge 306 to turn the transistor 111 off in the switching cycle 309 of the present control cycle N. The curve 302 shows the transistor gate-source voltage VGSSS2(N) in the switching cycle 309 of the present control cycle N. The edges of the VGSSS2(N) signal are delayed by a non-zero gate delay time t_GDelay from the corresponding edges of the PWM signal EPWMSS2(N).

The curve 303 shows the first pulse signal EQEPSS2(N) generated by the pulse generator 120 at the first output 124 in the switching cycle 309 of the present control cycle N. The first pulse signal EQEPSS2(N) in this example has a first edge 307 at time T3 (e.g., a rising edge) and a second (e.g., falling) edge 308 at time T4 indicating third quadrant conduction.

The curve 304 shows the second pulse signal ECAPSS2(N) generated by the pulse generator 120 at the first output 125 in the switching cycle 309 of the present control cycle N. The second pulse signal ECAPSS2(N) has a first (e.g., rising) edge at time T4 and a second (e.g., falling) edge at time T6 in the switching cycle 309.

At 206 in FIG. 2, the controller 150 determines whether the transistor undergoes third quadrant conduction at turn on. In one example, the controller 150 detects third quadrant conduction based on the presence or absence of pulse edges in the first pulse signal EQEPSS2(N) in the switching cycle 309 of the present control cycle N. If so (YES at 206), the method 200 proceeds to 208 and the controller 150 adjusts (e.g., moves) the turn on edge of the PWM signal EPWMSS2(N+1) forward (earlier in time) for the subsequent control cycle N+1. The graph 300 in FIG. 3A shows an example in which the controller 150 adjusts the turn on edge of the PWM signal EPWMSS2(N+1) forward by an increment labeled t_advance from time T4 to time T2. Otherwise (NO at 206), the method 200 proceeds to 209 and the controller 150 adjusts (e.g., moves) the turn on edge of the PWM signal EPWMSS2(N+1) backward (later in time) for the switching cycles of the subsequent control cycle N+1. At 210, the controller 150 determines the pulse length for the present control cycle N.

At 212, the controller 150 constructs the PWM signal EPWMSS2(N+1) for the next control cycle N+1 based on the turn on edge and pulse length of the present control cycle N and continues operation in the present control cycle at 214 before returning to begin the next cycle at 202. In the example of FIG. 3A, the controller 150 receives the first and second pulse signals EQEPSS2(N) and ECAPSS2(N) that were generated based on the electrical signal response of the transistor 111 to the applied PWM signal EPWMSS2(N) of the current control cycle N, and based on these, identifies a target (e.g., ideal) turn on point at time T4 and a target (e.g., ideal) turn off point at time T6 in the graph 300 of FIG. 3A. In one example, the pulse generator 120 generates the pulse signal EQEPSS2(N) that represents third quadrant conduction of the transistor 111 based on the measured electrical signal or signals VDS, VGS, and/or IS of the transistor 111 responsive to the PWM signal EPWMSS2(N) of the switching cycle 309 of the present control cycle N, and the controller 150 determines the target turn on point (e.g., T4) based on the pulse signal EQEPSS2.

In one example, as shown in the graph 310 of FIG. 3B, the controller 150 adjusts the temporal positions of the turn on edge 315 and the turn off edge 316 of the PWM signal EPWMSS2(N+1) for the next control cycle N+1 based on the target turn on and turn off points determined from the first and second pulse signals EQEPSS2(N) and ECAPSS2(N).

FIG. 3B shows the graph 310 having signal curves 311, 312, 313, and 314 in an example switching cycle 319 of the subsequent switching cycle N+1. The graph 310 shows events at marked times T11, T12, T13, T14, T15, and T16 in the switching cycle 319 that respectively correspond, relative to the beginning of the respective switching cycle, to the times T1-T6 in the earlier switching cycle 309 of FIG. 3A. The curve 311 shows the PWM signal EPWMSS2(N+1) having a first edge 315 at time T12 to turn the transistor 111 on and a second edge 316 to turn the transistor 111 off at time T15 in the switching cycle 319 of the subsequent control cycle N+1. The curve 312 shows the transistor gate-source voltage VGSSS2(N+1) in the switching cycle 319 of the subsequent control cycle N+1. The edges of the VGSSS2(N+1) signal are delayed by the non-zero gate delay time t_GDelay from the corresponding edges of the PWM signal EPWMSS2(N+1).

In this control cycle N+1, however, the adjustment of the PWM signal EPWMSS2(N+1) forward (e.g., earlier in the switching cycle 319) mitigates or avoids third quadrant conduction by the transistor 111, indicated by the first pulse signal EQEPSS2(N+1) with no pulse edges, shown in the curve 313. The curve 313 shows the first pulse signal EQEPSS2(N+1) generated by the pulse generator 120 at the first output 124 in the switching cycle 319 of the subsequent control cycle N+1 and is responsive to the PWM signal EPWMSS2(N+1) applied in the switching cycle of the subsequent control cycle N+1. The first pulse signal EQEPSS2(N+1) in this example has no rising or falling edges and indicates no third quadrant conduction by the transistor 111 in the switching cycle 319. The curve 314 shows the second pulse signal ECAPSS2(N+1) generated by the pulse generator 120 at the first output 125 in the switching cycle 319 of the subsequent control cycle N+1. The second pulse signal ECAPSS2(N+1) has a first (e.g., rising) edge at time T4 and a second (e.g., falling) edge at time T6 and a pulse length TIPW that corresponds to the temporal difference T6-T4, which is the same as the difference between the target (e.g., ideal) turn on point and the target (e.g., ideal) turn off point in the graph 300 of FIG. 3A for the present control cycle N.

The controller 150 in one example determines the target turn on point (e.g., at time T4 in FIG. 3A) based on a measured electrical signal (e.g., VDS, VGS, IS) of the transistor 111 responsive to the PWM signal EPWMSS2(N) of a switching cycle 309 of the present control cycle N. The controller 150 in this example determines the target turn off point (e.g., T6 in FIG. 3A) based on the measured electrical signal VDS, VGS, IS of the transistor 111. Based on the determined target turn on point, the controller 150 adjusts the first edge 315 of the PWM signal EPWMSS2(N+1) for the switching cycle 319 of the subsequent control cycle N+1. In addition, the controller 150 in one implementation adjusts the second edge 316 of the PWM signal EPWMSS2(N+1) for the switching cycle 319 of the subsequent control cycle N+1 based on the determined target turn off point. In one implementation, the controller 150 adjusts the first edge 316 of the PWM signal EPWMSS2(N+1) forward (e.g., at 208 in FIG. 2) for the switching cycle 319 of the subsequent control cycle N+1 in response to the target turn on point indicating third quadrant conduction of the transistor 111 in the switching cycle 309 and adjusts the first edge 316 of the PWM signal EPWMSS2(N+1) backward (e.g., at 209) for the switching cycle 319 of the subsequent control cycle N+1 in response to the target turn on point indicating no third quadrant conduction of the transistor 111 in the switching cycle 309 of the present control cycle N.

FIG. 4 shows another example pulse timing adjustment control method 400 that can be implemented by the controller 150. In this example, the controller 150 applies the PWM signal based on the information from the previous cycle in each of an integer number M switching cycles of the present control cycle N, where M is greater than 2. The controller 150 in this example counts the number of switching cycles “X” for which third quadrant conduction occurs in the present control cycle N, and selectively adjusts the turn on edge forward or backward, or makes no change depending on comparison of the count value X with first and second thresholds TH1 and TH2. This approach provides a dead band between the thresholds that mitigates changes where the operation is close to the minimum third quadrant conduction level achievable. The method 400 starts a present cycle N at 402 in FIG. 4. At 404, for M switching cycles of the present control cycle N, the controller 150 generates the PWM signal EPWMSS2(N) based on turn on edge and pulse length information from the previous control cycle N−1. At 405 in FIG. 4, the controller 150 counts the number “X” third quadrant pulses received during the present control cycle, for example, the number of switching cycles for which the measured electrical signal (e.g., VDS, VGS, IS, etc.) indicates third quadrant conduction of the transistor 111 in the respective switching cycle.

At 406 in FIG. 4, the controller 150 determines whether the count value X is greater than the first threshold TH1 for the M switching cycles 309, 319 of the present control cycle N. If so (YES at 406), the controller 150 responds at 408 by adjusting the first edge of the PWM signal EPWMSS2(N+1) forward for the switching cycles of the subsequent control cycle N+1. If not (NO at 406), the controller 150 determines at 407 whether the count value X is less than a lower second threshold TH2 (e.g., TH1 is greater than TH2). If so (YES at 407), the controller 150 responds at 409 by adjusting 188 the first edge 316 of the PWM signal EPWMSS2(N+1) backward for the switching cycles of the subsequent control cycle N+1. If the count value X is between the thresholds TH1 and TH2 (NO at 407), the controller 150 does not modify the PWM signal EPWMSS2(N+1) for the subsequent control cycle N+1. At 410 in FIG. 4, the controller 150 determines the pulse length for the present control cycle N. At 412, the controller 150 constructs the PWM signal EPWMSS2(N+1) for the next control cycle N+1 based on the turn on edge and pulse length of the present control cycle N and continues operation in the present control cycle at 414 before returning to begin the next cycle at 402. While the method 200 can lead to dithering the PWM signal turn on edge forward and backward in successive control cycles during steady state output regulator conditions, the method 400 can mitigate or avoid constant dithering at steady state, and also mitigates or avoids noise triggered dithering. The method 400 still facilitates mitigation of third quadrant conduction of the transistor 111 by moving the turn on edge forward if the number of third quadrant conduction switching cycles in one control cycle is too high, and by moving the turn on edge backward if the number of third quadrant conduction switching cycles in one control cycle is too low.

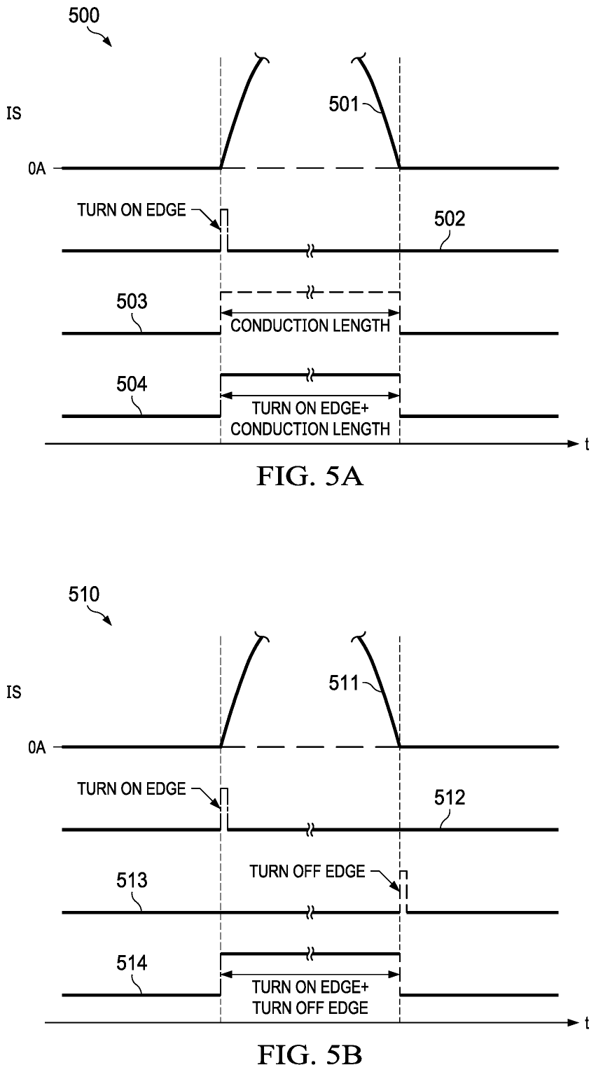

Referring also to FIGS. 5A and 5B, FIG. 5A includes a signal diagram 500 having curves 501, 502, 503, and 504 that show example switching rectifier turn on and conduction length signals, and FIG. 5B includes a signal diagram 510 having curves 511, 512, 513, and 514 that show example switching rectifier turn on and turn off signals. The curve 501 in the signal diagram 500 shows the source current IS of the transistor 111 during an example switching cycle, and the curve 502 shows a pulse signal with a rising edge at a target turn on point for the transistor 111. The curve 503 shows a pulse signal having a target conduction length (e.g., also referred to as a pulse width or pulse length), and the curve 504 shows a pulse signal formed using the turn on edge of the curve 502 and the turn off (e.g., falling) edge of the curve 503. The resulting pulse signal shown by the curve 504 in one example represents target or ideal turn on and turn off points for operating the transistor 111.

The signal diagram 510 in FIG. 5B includes a curve 511 that shows the source current IS of the transistor 111 during the example switching cycle. The curve 512 shows a pulse signal with a rising edge at a target turn on point for the transistor 111, similar to the pulse shown in the curve 502 of FIG. 5A above. The curve 513 shows a pulse signal having a first (e.g., rising) edge at a target (e.g., ideal) turn off point for the transistor 111. In this example, the curve 514 shows a pulse signal formed using the turn on edge of the curve 512 and the turn off edge of the curve 513. The resulting pulse signal shown by the curve 514 is the same as the pulse shown by the curve 504, and the controller 150 can implement the target or ideal pulse shown by the curves 504 and 514 based on the type of information received in the curves 502 and 503 of FIG. 5A or based on the type of information received in the curves 512 and 513 of FIG. 5B. Moreover, the above methods 182, 200, and 400 and the pulse generator 120 and controller 150 in FIG. 1 can be employed to adaptively mitigate or eliminate third quadrant conduction for transistors and asynchronous rectifier or other switching power supply type even in systems where the signal chain delay between the transistor 111 and the controller 150 is unknown and/or variable. The controller 150 in the above examples receives information from the pulse generator 120 regarding the transistor turn on and pulse length or the transistor turn on and turn off and uses this information to re-create or reconstruct the ideal for improved gate control signal for use in subsequent control cycles to compensate for propagation delay from PWM signal generation to the transistor gate. This approach adjusts the forward time for the recreated PWM signal and facilitates mitigation or reduction of third quadrant conduction even in the presence of large and/or varying signal chain propagation delays.

Referring also to FIGS. 6A, 6B and 1A above, FIG. 6A shows a signal diagram 600 having signal curves 601, 602, 603, 604, and 605 in an example switching cycle of the present control cycle N. The signal diagram 600 shows drain-source voltage, gate-source voltage and pulse generator signals in a present control cycle using turn on edge control. FIG. 6B shows a signal diagram 610 having signal curves 611, 612, 613, 614, and 615 in an example switching cycle of the subsequent control cycle N+1. The signal diagram 600 shows drain-source voltage, gate-source voltage and pulse generator signals in the subsequent control cycle N+1 using turn on edge control. The curve 601 shows the drain-source voltage VDSSS2(N) for the present control cycle N, and the curve 602 in FIG. 6A shows a threshold (e.g., −1 V) to which the drain-source voltage curve 601 as compared by the pulse generator 120. The curve 603 shows the PWM signal EPWMSS2(N) of the current control cycle N. The curve 604 shows the gate-source voltage VGSSS2(N) for the present control cycle N, and the curve 605 shows the first pulse signal EQEPSS2(N) that indicates the presence of third quadrant conduction by the transistor 111. In this example, the controller 150 determines the adjustment of the turn on PWM signal position in the subsequent control cycle N+1 as a function of the present amount of forward adjustment FW(N) plus a temporal step amount STP (e.g., FW(N+1)=FW(N)+STP). The pulse generator 120 in this example generates the leading (e.g., rising) edge of the first pulse signal EQEPSS2(N) in response to detection of the drain-source voltage curve 601 transitioning downward to and beyond the threshold 602. In this example, the pulse generator 120 generates the second (e.g., falling) edge of the first pulse signal EQEPSS2(N) in response to detection of the drain-source voltage curve 601 transitioning upward to and beyond the threshold 602. In this example, the drain-source voltage is used by the pulse generator 122 estimate the temporal duration of third quadrant conduction by the transistor 111 without requiring current sensing circuitry or connections.

The signal diagram 610 in FIG. 6B illustrates the corresponding signals for the subsequent control cycle N+1 The curve 611 shows the drain-source voltage VDSSS2(N) for the present control cycle N, and the curve 612 in FIG. 6A shows a threshold (e.g., −1 V) to which the drain-source voltage curve 611 as compared by the pulse generator 120. The curve 613 shows the PWM signal EPWMSS2(N) of the current control cycle N. The curve 614 shows the gate-source voltage VGSSS2(N) for the present control cycle N, and the curve 615 shows the first pulse signal EQEPSS2(N) with no rising or falling edges, indicating that the adjustment by the controller 150 eliminated or reduced third quadrant conduction by the transistor 111 in the control cycle N+1.

Referring now to FIGS. 7A and 7B, FIG. 7A shows a signal diagram 700 with curves 701, 702, 703, and 704 that illustrate example transistor current, gate-source voltage and pulse generator signals in a present control cycle N using turn off edge control. FIG. 7B includes a signal diagram 710 having curves 711, 712, 713, and 714 that show transistor current, gate-source voltage and pulse generator signals in a subsequent control cycle N+1 using turn off edge control. The curves 701 and 711 in this example show the transistor source current IS, the curves 702 and 712 show the PWM signal EPWMSS2 of the respective control cycles, the curves 703 and 713 show the respective transistor gate-source voltage curves VGSSS2, and the curves 704 and 714 show a computed pulse generated by the controller 150 for the respective control cycles. In this example, the gate-source voltage curve 703 for the present control cycle N has a duration or pulse width that corresponds to the second pulse signal ECAP(N) provided by the pulse generator 120, and the duration of the computed pulse shown by the curve 704 is dFW(N+1)+ECAPSS2(N). For the subsequent control cycle (N+1), the signal diagram 710 shows the gate-source voltage curve 713 having a duration or pulse width that corresponds to the second pulse signal ECAPSS2(N+1), and the duration of the computed pulse shown by the curve 704 is dFW(N+2)+ECAPSS2(N+1). In one example, the controller 150 uses this pulse length of the second pulse signal ECAPSS2(N) to set or determine a target turn off point or to adjust a turn off time or point in switching cycles of a subsequent control cycle. In one implementation, the controller 150 uses an internal counter to count the length of the pulse from pulse generator 120, and the resulting ECAP count is used in the next cycle to create the PWM signal EPWMSS2.

FIG. 8 includes a signal diagram 800 having curves 801-806 and 811-816 that show primary and secondary side modulation reference and carrier signals as well as pulse generator signals for turn on and turn off edge control of the primary and secondary side transistors 111 in the synchronous rectifier system 100 of FIG. 1. This example uses offset primary side modulation signals 802 and 803 respectively above and below a nominal reference signal 804. The controller 150 compares the present value of the corresponding primary side carrier signal 801 to the modulating signals 802 and 803 to generate the respective lower PWM curve 806 (EPWMSP2) and the upper PWM curve 805 (EPPWMSP1). The offset of the modulating signals 802 and 803 provides a controlled dead band timing Tdb_P and Tdb_S for the respective primary and secondary switching circuits. In this example, the secondary side pulse width modulation uses a second carrier signal shown by the curve 811, along with first and second modulation signal curves 812 and 813 respectively offset above and below a nominal secondary side reference signal 814. The controller 150 compares the present value of the corresponding secondary side carrier signal 811 to the modulating signals 812 and 813 to generate the respective lower PWM curve 816 (EPWMSS2) and the upper PWM curve 815 (EPWMSS1). The signal diagram 800 in FIG. 8 shows a change in the output requirement of the load 131, which increases the offset in the modulating signals 812 and 813 between the first switching cycle and the second illustrated switching cycle. In addition, the signal diagram 800 and FIG. 8 shows adjusted portions of the PWM signals EPWMSS1 and EPWMSS2 by the controller 150 implementing the above pulse timing adjustment control, for example, according to one of the methods 200 or 400 described above. In another example, comparators and trying to wave generators are used for hardware implementation of pulse timing adjustment control and pulse width modulation signal generation. Various implementations provide hardware and/or firmware modulation, such as the illustrated DSP controller example to adaptively adjust both turn-on and turn-off edge, referenced to the primary side PWM signals. In one example, the primary side PWM signals have duty cycles fixed at 50% for current symmetry, and the controller 150 implements dead-band time adjustment and phase shift adjustment. In one example, zero-voltage detection (ZVD) sensing circuitry (e.g., separate or in the integrated transistor/driver devices 110) adjusts a pulse position by a shift time amount Tshift shown in FIG. 8, and zero-current detection (ZCD) sensing circuitry (e.g., separate or in the integrated transistor/driver devices 110) adjusts the secondary side dead-band duration Tdb_S (e.g., pulse length). In one example, Tdb_S=0.5*Tsw−ECAP(n−1), where Tsw is the switching frequency of the PWM circuitry, and Tshift=(Tdb_P−FW(n)−Tdb_S)/2*Tsw.

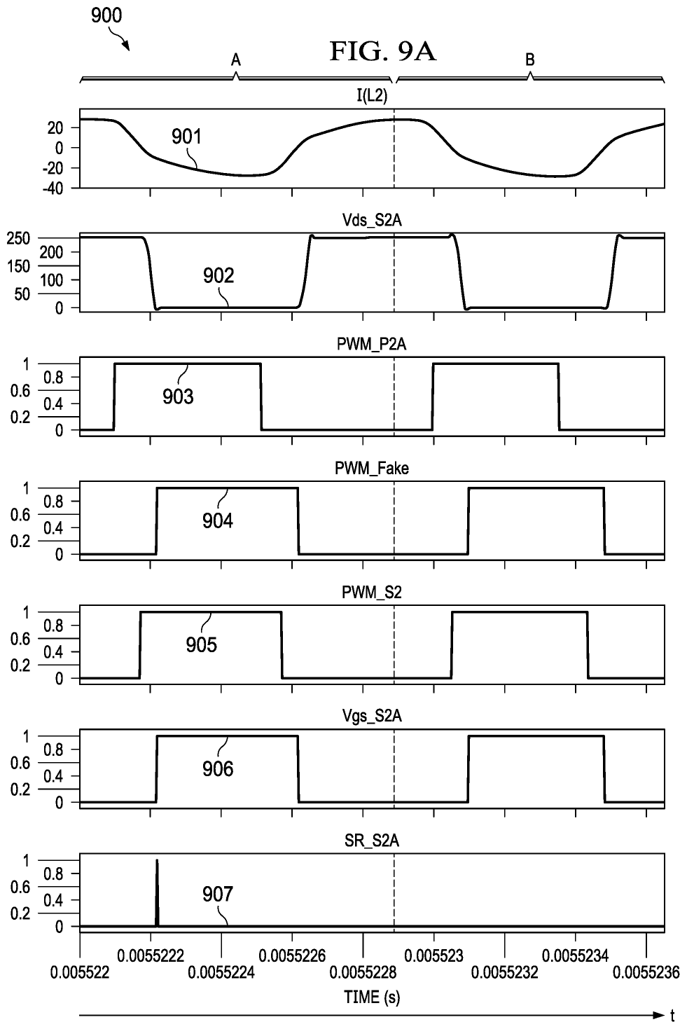

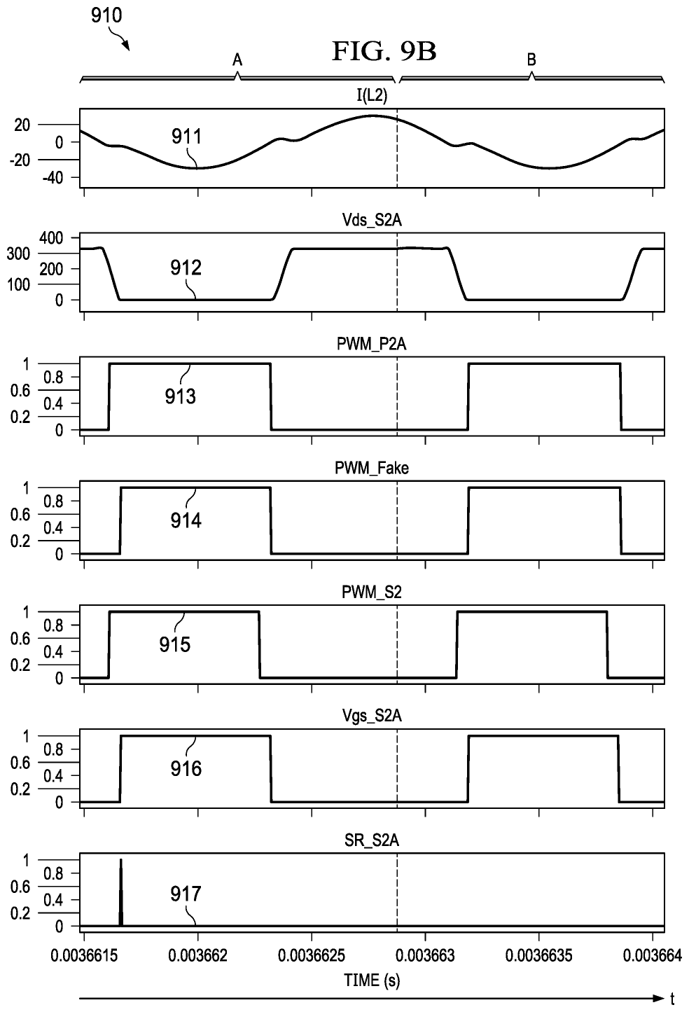

Referring now to FIGS. 9A and 9B, FIG. 9A includes a timing diagram 900 with curves 901-907 that show simulated power converter signals with phase shift, and FIG. 9B includes a timing diagram 910 with curves 911-917 showing comparative simulated power converter signals without phase shifting. The curves 901 and 911 represent the secondary side inductor current IL, and the curves 902 and 912 represent the drain-source voltage VDS of the lower secondary side transistor 111, the curves 903 and 913 represent the lower primary side PWM signal EPWMSP2. In addition, the curves 904 and 914 show fake PWM signals, and the curves 905 and 915 show the lower secondary side PWM signal EPWMSS2. The curves 906 and 916 represent the gate-source voltage VGS of the lower secondary side transistor 111, and the curves 907 and 917 show the first pulse signal EQEPSS2 generated by the pulse generator 120. FIGS. 9A and 9B show to example switching cycles with delay prediction at operation above resonant frequency, and the synchronous rectifier secondary side switching is phase shifted from the primary. In the illustrated example, the third quadrant conduction is eliminated in the second illustrated cycle, and this implementation avoids or mitigates sensing noise at the pulse turn off edge.

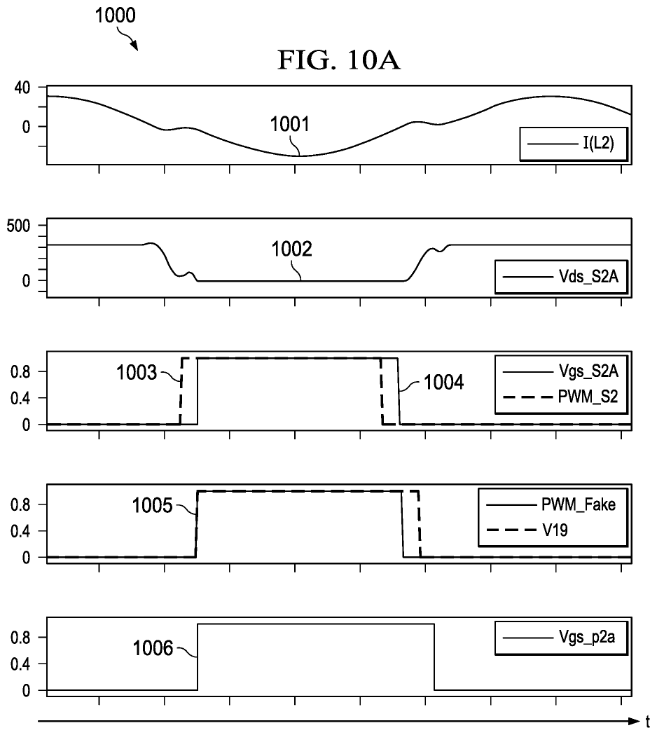

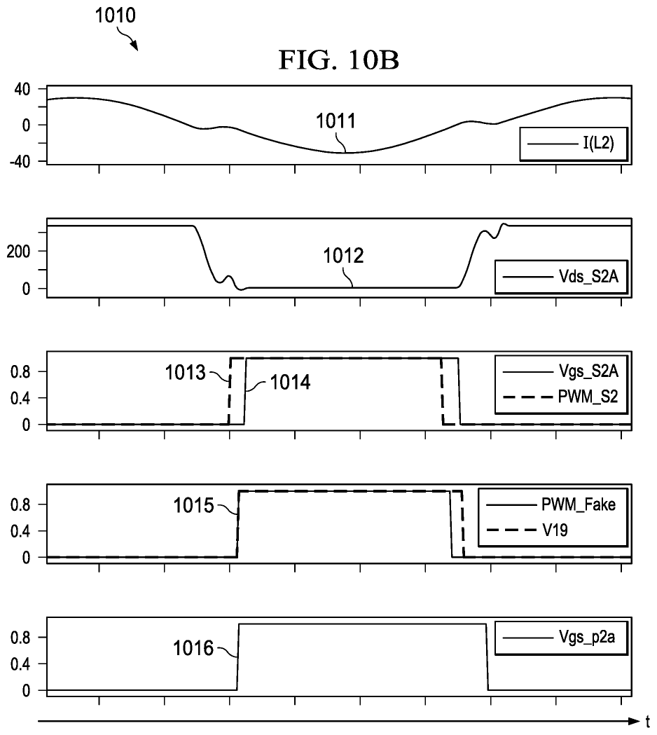

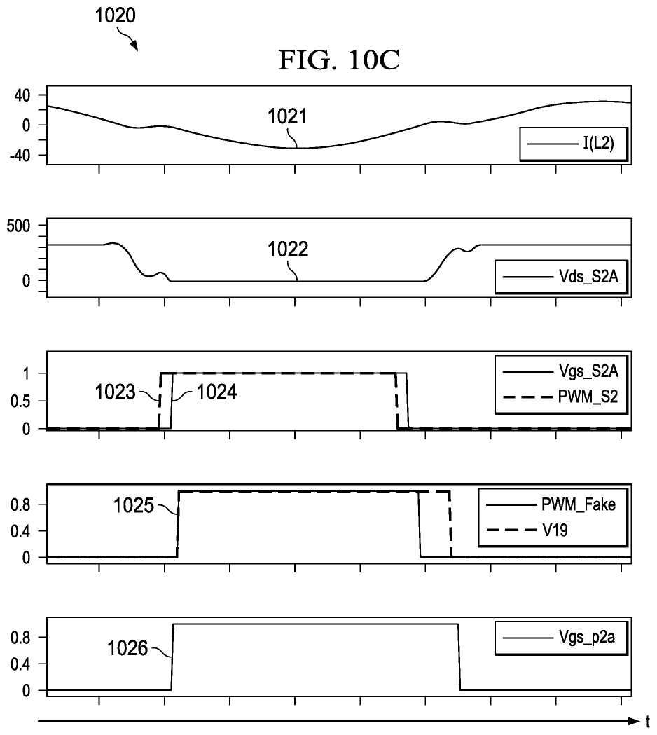

Referring also to FIGS. 10A, 10B, and 10C, FIG. 10A includes a signal diagram 1000 with curves 1001-1008 that show simulated power converter signals where an estimated delay equals a real delay. FIG. 10B includes a signal diagram 1010 with curves 1011-1016 that show simulated power converter signals where an estimated delay is less than a real delay, leading to extra loss on both turn on and off edges. FIG. 10C includes a signal diagram 1020 with curves 1021-1028 that show simulated power converter signals where an estimated delay is greater than a real delay, which leads to extra turn off edge loss. The curves 1001, 1011, and 1021 show the inductor current IL, the curves 1002, 1012, and 1022 show the upper secondary side drain-source voltage VDS, the curves 1003, 1013, and 1023 show the PWM signals EPWMSS for the lower secondary side transistor 111, and the curves 1004, 1014, and 1024 show the gate-source voltage signals VGS for the lower secondary side transistor 111. The curves 1005, 1015, and 1025 show fake PWM signals, and the curves 1006, 1016, and 1026 show the gate-source voltages for the upper primary side transistor 111.

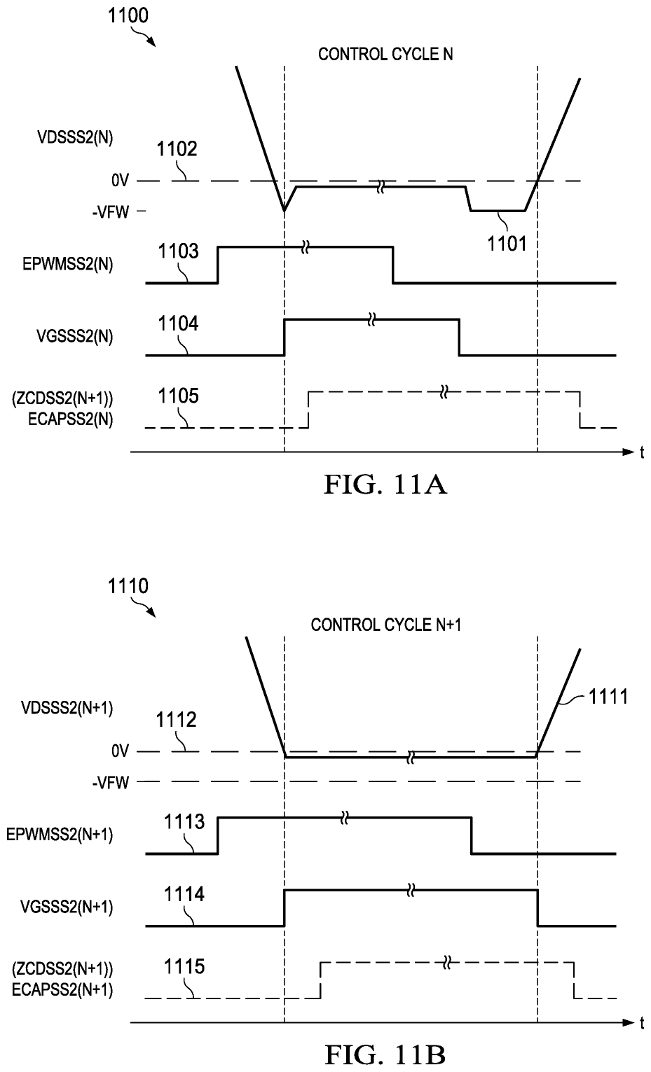

Referring now to FIGS. 11A and 11B, FIG. 11A includes a signal diagram 1100 with curves 1101, 1102, 1103, 1104, and 1105 that show transistor voltage, gate-source voltage and pulse generator signals in a present control cycle N using pulse length control in the synchronous rectifier system 100 of FIG. 1. FIG. 11B includes a signal diagram 1110 with curves 1111, 1112, 1113, 1114, and 1115 that show transistor current, gate-source voltage and pulse generator signals in a subsequent control cycle N+1 using pulse length edge control. The curves 1101 and 1111 show the drain-source voltage signals VDSSS2 for the respective present and subsequent control cycles, and the curves 1102 and 1112 show a threshold (e.g., 0 V) to which the drain-source voltage signals are compared by the pulse generator 120. The curves 1103 and 1113 show the PWM signal EPWMSS2 for the respective present and subsequent control cycles, and the curves 1104 and 1114 show the transistor gate-source voltage signals VGSSS2 for the respective present and subsequent control cycles. The curves 1105 and 1115 show the second pulse signal ECAPSS2 for the respective present and subsequent control cycles. In this example, the pulse generator 120 generates the second pulse signal ECAPSS2(N) (curve 1105) having a target pulse width or pulse length, and the controller 150 generates the PWM signal EPWMSS2(N+1) for the subsequent control cycle N+1 with the target pulse width.

FIG. 12 shows a power conversion system 1200 with pulse timing adjustment by a controller to mitigate third quadrant conduction of switching transistors using timing information from an external pulse generator. The power conversion system 1200 has a secondary side circuit with a synchronous rectifier and includes similarly numbered components as illustrated and described above in connection with the system 100 of FIGS. 1-1E except as noted herein.

In this example, the pulse generator functions are implemented using separate electronic devices 1200 individually coupled with a corresponding one of the respective transistors 111 of the primary and secondary side circuitry. The system 1200 includes integrated driver/transistor devices 1210 having the driver 115 and transistor 111 as described above. The pulse generators 1220 each have a first input 1221, a second input 1222, a third input 1223, a first output 1224, a second output 1225, and a current sense input 1227. The pulse generator 1220 is as described above in connection with the pulse generator 120 and provides the above described first and second pulse signals EQSP and ECAP through the associated isolation circuit 153, 163 to the controller 150. For each of the pulse generators 1220 in FIG. 12, the first input 1221 is coupled to the source 112 of the transistor 111. The second input 1222 is coupled to the drain 113 of the transistor 111. The third input 1223 is coupled to the gate 114 of the transistor 111. The current sense input 1227 senses the source current IS of the transistor 111. The pulse generator 1220 is a circuit having electronic components such as transistors, resistors, capacitors, amplifiers, etc., that are configured to generate one or more pulse signals at the respective outputs 1224 and 1225.

FIG. 13 shows a power conversion system 1300 with pulse timing adjustment by the controller 150 to mitigate third quadrant conduction of switching transistors using timing information from a pulse generator in a half bridge secondary circuit. The power conversion system 1300 has a secondary side circuit with a synchronous rectifier. The power conversion system 1300 includes similarly numbered components as illustrated and described above in connection with the system 100 of FIGS. 1-1E except as noted herein. In this example, the pulse generators 120 are as described above, but only a single pulse output is used from each individual pulse generator 120. This configuration reduces the number of isolation channels of the respective isolation circuits 153 and 163. The first output 124 of the pulse generator 120 of the driver/transistor device 110 of the primary circuit labeled “SP1” provides the first pulse signal ZVDSP1 to the isolation circuit 163, and the second output 125 of the pulse generator 120 of the driver/transistor device 110 of the primary circuit labeled “SP2” provides the second pulse signal ZCDSP2 to the isolation circuit 163. The isolation circuit 163 provides corresponding isolated pulse signals EQEPSP1 and ECAPSP2 to the controller 150. For the secondary side circuitry, the first output 124 of the pulse generator 120 of the driver/transistor device 110 of the secondary circuit labeled “SS1” provides the first pulse signal ZVDSS1 to the isolation circuit 153, and the second output 125 of the pulse generator 120 of the driver/transistor device 110 of the secondary circuit labeled “SS2” provides the second pulse signal ZCDSS2 to the isolation circuit 153. The isolation circuit 153 provides corresponding isolated pulse signals EQEPSS1 and ECAPSS2 to the controller 150. The controller 150 in one example operates as described above.

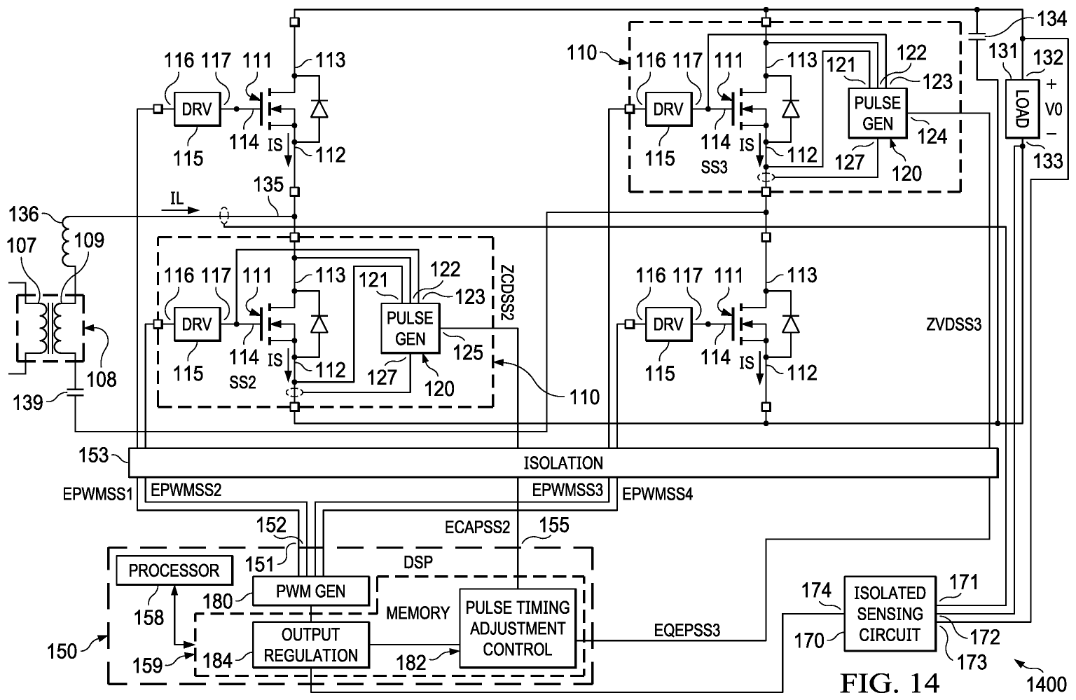

FIG. 14 shows another power conversion system 1400 with pulse timing adjustment by the controller 150 to mitigate third quadrant conduction of switching transistors using timing information from pulse generators at two corners of a full bridge secondary circuit. The power conversion system 1400 includes similarly numbered components as illustrated and described above in connection with the system 100 of FIGS. 1-1E except as noted herein. In this example, the primary side circuitry (not shown in FIG. 14) is as described above. In addition, the pulse generators 120 are as described above, but only a single pulse output is used from each individual pulse generator 120. The system 1400 includes a full bridge (e.g., H-bridge) configuration of integrated driver/transistor devices 110 of the secondary circuit, including a first branch with integrated driver/transistor devices 110 labeled SS1 and SS2, as well as a second circuit branch with integrated driver/transistor devices 110 labeled SS3 and SS4. The individual integrated driver/transistor devices 110 in two corners of the full bridge, SS2 and SS3 in this example, include an integrated pulse generator 120. In another example, the individual integrated driver/transistor devices 110 in the other two corners of the full bridge (e.g., SS1 and SS4) include an integrated pulse generator 120.

In this example, the pulse generators 120 are as described above, but only a single pulse output is used from each individual pulse generator 120. This configuration reduces the number of isolation channels of the isolation circuit 153. The first output 124 of the pulse generator 120 of the driver/transistor device 110 of the secondary circuit labeled “SS3” provides a first pulse signal ZVDSS3 to the isolation circuit 153, and the second output 125 of the pulse generator 120 of the driver/transistor device 110 of the secondary circuit labeled “SS2” provides the second pulse signal ZCDSS2 to the isolation circuit 153. The isolation circuit 153 provides corresponding isolated pulse signals EQEPSS3 and ECAPSS2 to the controller 150. The controller 150 in one example operates as described above. In the full bridge configuration of FIG. 14, the transistors 111 of the driver/transistor devices 110 labeled SS2 and SS3 conduct together and the respective pulse generators 120 provide the ZCDSS2 and ZVDSS3 pulse signals to the controller as the isolated pulse signals ECAPSS2 and EQEPSS3 via the isolation circuit 153.

The controller 150 in one example operates as described above to implement pulse timing adjustment based on the isolated pulse signals ECAPSS2 and EQEPSS3 to mitigate third quadrant conduction of switching transistors 111 of the full bridge secondary circuit. In one example, for a given control cycle (e.g., N), the controller 150 uses the presence or absence of an EQEPSS3 pulse to determine whether to move the turn on edge for the next cycle (N+1) forward or backward, and the controller 150 uses the pulse length of the ECAPSS2 pulse of the given control cycle N to set the on-time of the transistor for the next control cycle N+1 as described above in connection with FIG. 2. In one implementation, the controller 150 uses the turn on edge information from the EQEPSS3 pulse and the on-time information from the ECAPSS2 pulse for both half-cycles of the full bridge of the secondary circuitry.

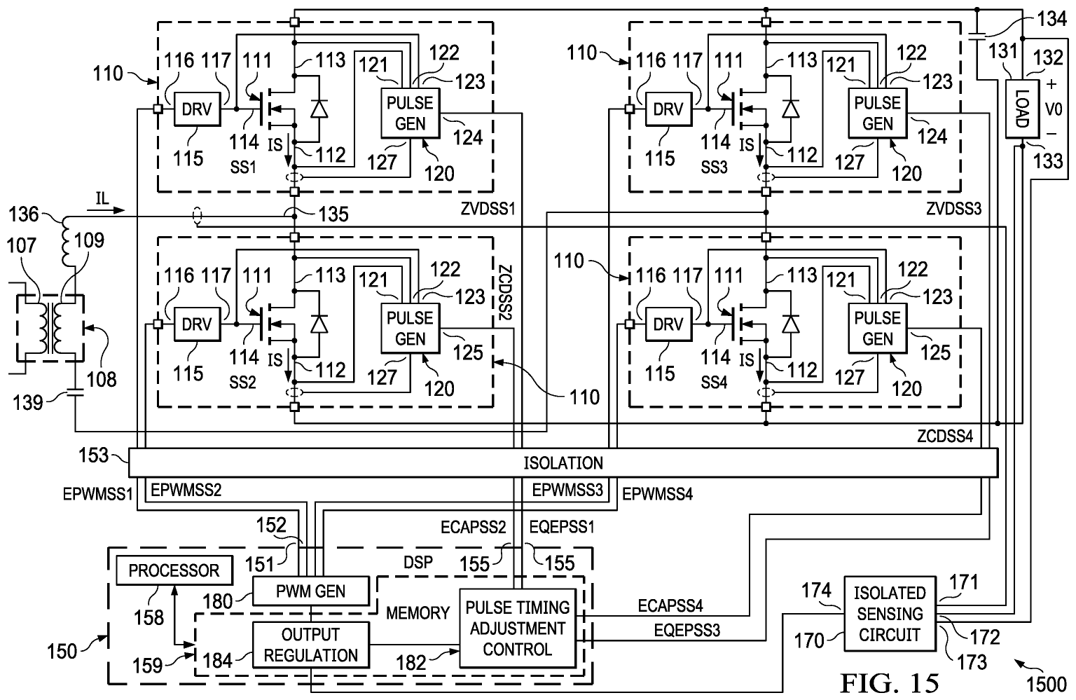

FIG. 15 shows another power conversion system 1500 with pulse timing adjustment by a controller to mitigate third quadrant conduction of switching transistors using timing information from pulse generators at four corners of a full bridge secondary circuit. The power conversion system 1500 includes similarly numbered components as illustrated and described above in connection with the system 100 of FIGS. 1-1E except as noted herein. In this example, the primary side circuitry (not shown in FIG. 15) is as described above. In addition, the pulse generators 120 are as described above, but only a single pulse output is used from each individual pulse generator 120. The system 1400 includes a full bridge (e.g., H-bridge) configuration of integrated driver/transistor devices 110 of the secondary circuit as described above in connection with FIG. 14. The individual integrated driver/transistor devices 110 in all four corners of the full bridge include an integrated pulse generator 120, and only a single pulse output is used from each individual pulse generator 120. This configuration reduces the number of isolation channels of the isolation circuit 153.

The first output 124 of the pulse generator 120 of the driver/transistor device 110 of the secondary circuit labeled “SS1” provides a first pulse signal ZVDSS1 to the isolation circuit 153, and the second output 125 of the pulse generator 120 of the driver/transistor device 110 of the secondary circuit labeled “SS2” provides the second pulse signal ZCDSS2 to the isolation circuit 153. In addition, the first output 124 of the pulse generator 120 of the driver/transistor device 110 of the secondary circuit labeled “SS3” provides a first pulse signal ZVDSS3 to the isolation circuit 153, and the second output 125 of the pulse generator 120 of the driver/transistor device 110 of the secondary circuit labeled “SS4” provides the second pulse signal ZCDSS4 to the isolation circuit 153. The isolation circuit 153 provides corresponding isolated pulse signals EQEPSS1, ECAPSS2, EQEPSS3 and ECAPSS4 to the controller 150. The controller 150 in one example operates as described above. In the full bridge configuration of FIG. 15, the transistors 111 of the driver/transistor devices 110 labeled SS2 and SS3 conduct together and the respective pulse generators 120 provide the ZCDSS2 and ZVDSS3 pulse signals to the controller as the isolated pulse signals ECAPSS2 and EQEPSS3 via the isolation circuit 153. In addition, the transistors 111 of the driver/transistor devices 110 labeled SS1 and SS4 conduct together and the respective pulse generators 120 provide the ZVDSS1 and ZCDSS4 pulse signals to the controller as the isolated pulse signals EQEPSS1 and ECAPSS4 via the isolation circuit 153.

The controller 150 in one example operates as described above to implement pulse timing adjustment based on the isolated pulse signals ECAPSS2 and EQEPSS3 in one half-cycle, and based on the isolated pulse signals EQEPSS1 and ECAPSS4 in the other half-cycle to mitigate third quadrant conduction of switching transistors 111 of the full bridge secondary circuit. In one example, the controller 150 determines whether to move the turn on edge for the next cycle (N+1) forward or backward based on the presence or absence of an EQEPSS3 or EQEPSS1 pulse, and the controller 150 sets the on-time of the transistor for the next control cycle based on the pulse length of the ECAPSS2 or ECAPSS4 pulse as described above in connection with FIG. 2.

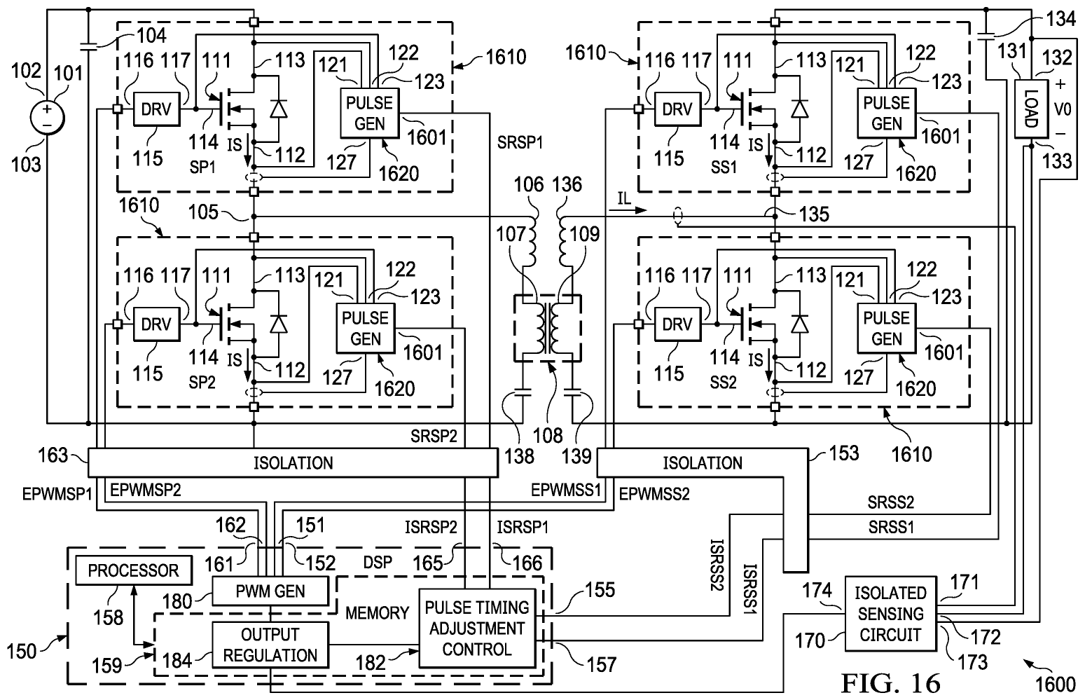

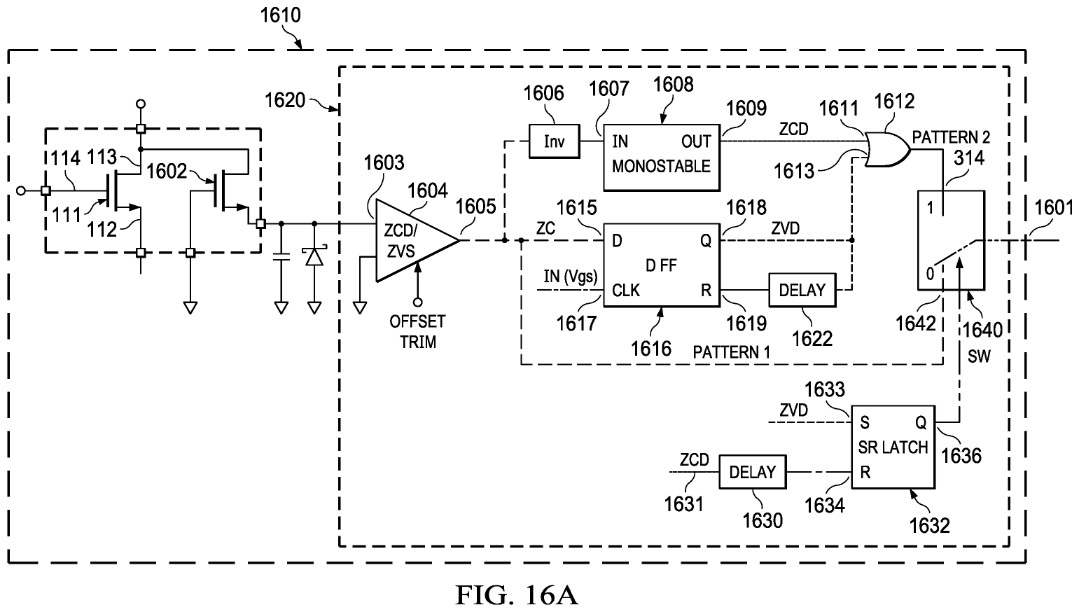

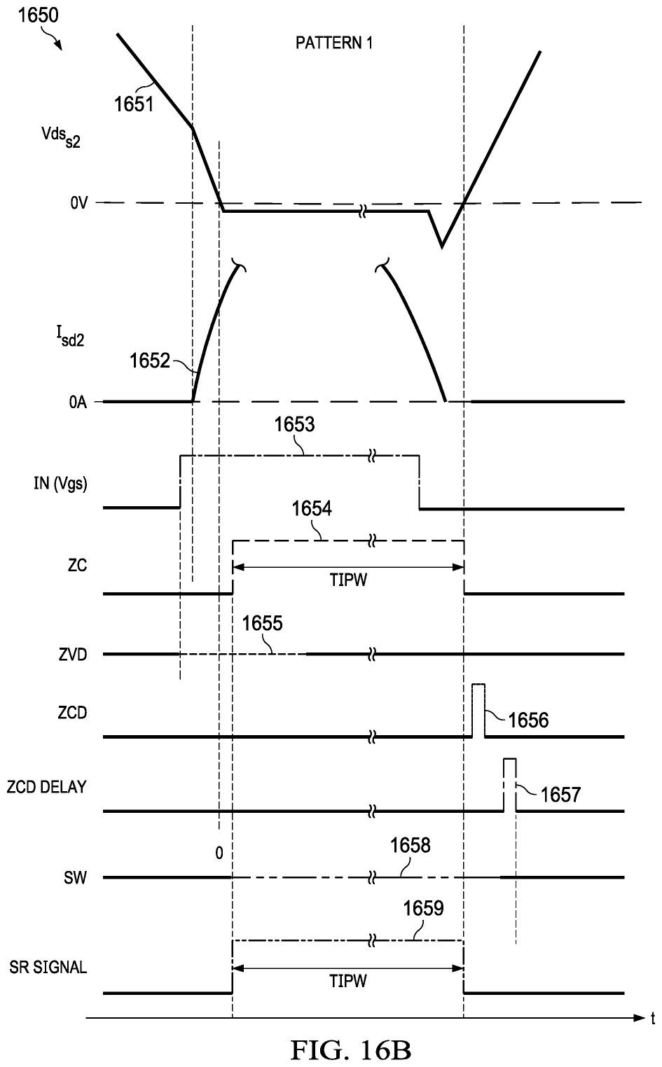

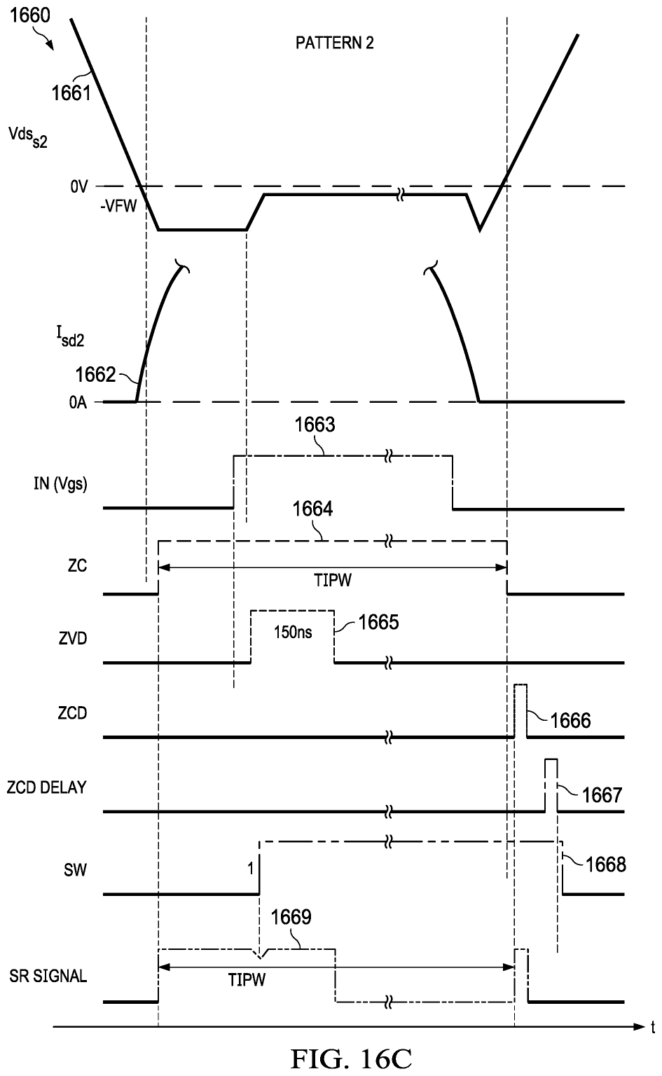

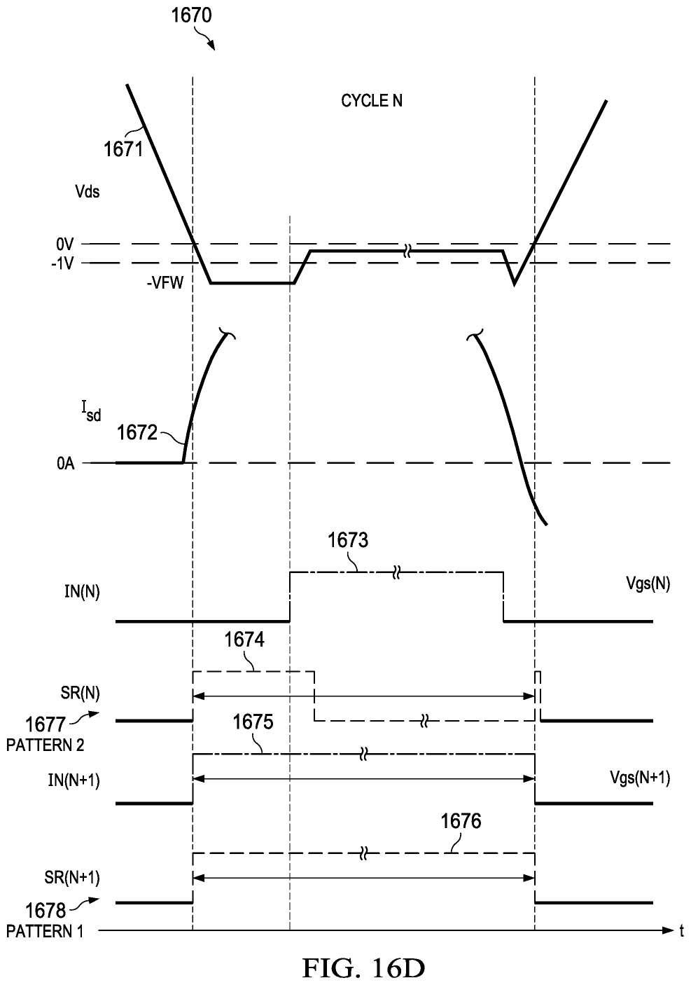

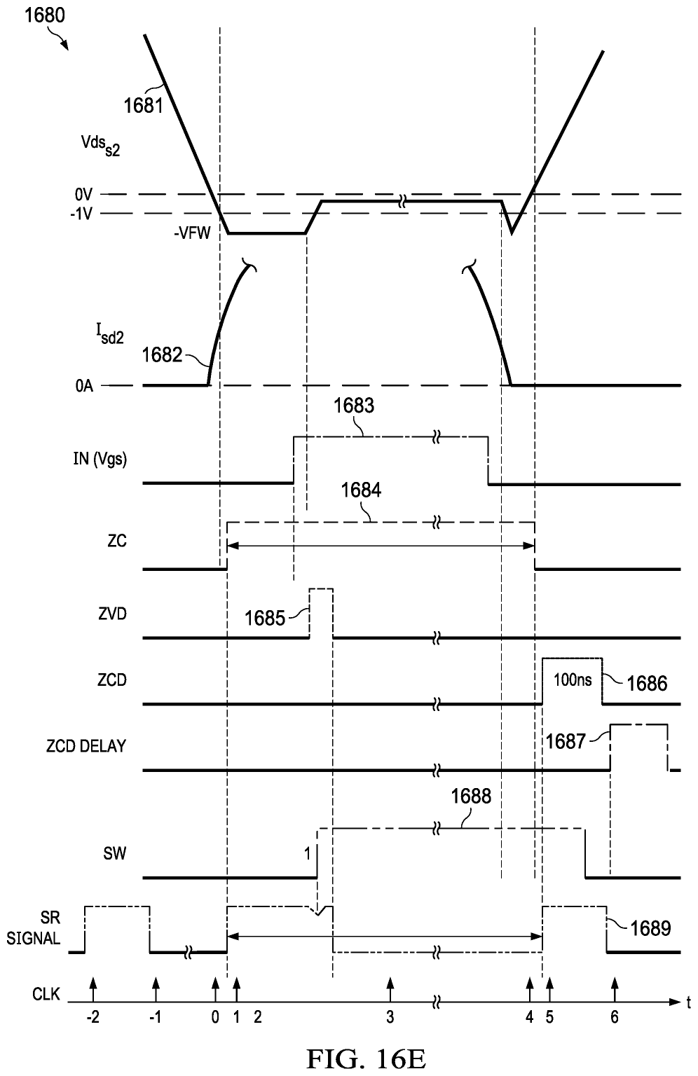

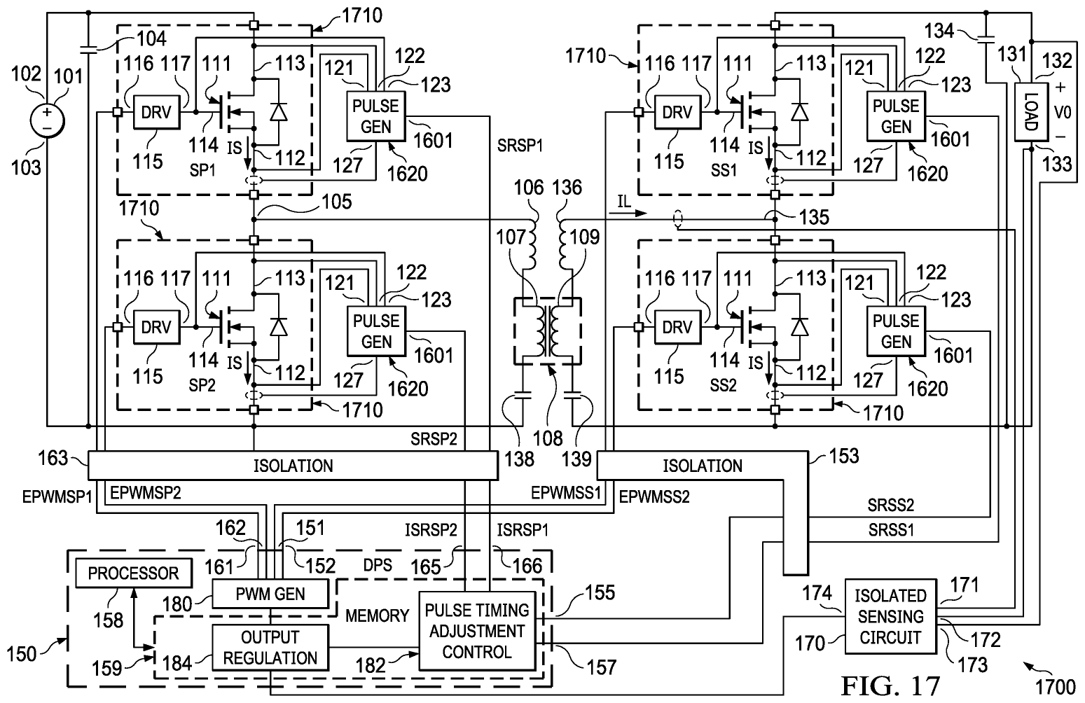

Referring to FIGS. 16, and 16A-16E, FIG. 16 shows another example power conversion system 1600 with pulse timing adjustment by the controller 150 to mitigate third quadrant conduction of switching transistors using timing information from a single output pulse generator 1620 integrated with a transistor in driver/transistor devices 1610 in a half bridge secondary circuit. FIG. 16A shows the single output pulse generator 1620 in the power conversion system 1600 of FIG. 16. FIG. 16B shows the output pulse signal SR of the single output pulse generator 1620 having a first pulse pattern in a present control cycle. FIG. 16C shows the output pulse signal SR having a second pulse pattern of the single output pulse generator of FIG. 16A in a present control cycle. FIG. 16D shows the first and second pulse patterns of the single output pulse generator 1620 of FIG. 16A. FIG. 16E shows another example pulse signal having another example second pulse pattern of another implementation of the single output pulse generator 1620 in a present control cycle. The power conversion system 1600 has a secondary side circuit with a synchronous rectifier. The power conversion system 1600 includes similarly numbered components as illustrated and described above in connection with the system 100 of FIGS. 1-1E except as noted herein. In this example, the individual pulse generators 1620 have a single pulse output 1601.

The output 1601 of the pulse generator 1620 of the driver/transistor device 1610 of the primary circuit labeled “SP1” provides a pulse signal SRSP1 having one of two patterns to the isolation circuit 163. The output 1601 of the pulse generator 1620 of the driver/transistor device 1610 of the primary circuit labeled “SP2” provides a pulse signal SRSP2 having one of two patterns to the isolation circuit 163. The isolation circuit 163 provides corresponding isolated pulse signals ISRSP1 and ISRSP2 to the controller 150. For the secondary side circuitry, the output 1601 of the pulse generator 1620 of the driver/transistor device 1610 of the secondary circuit labeled “SS1” provides a pulse signal SRSS1 having one of two patterns to the isolation circuit 153. The output 1601 of the pulse generator 1620 of the driver/transistor device 1610 of the secondary circuit labeled “SS2” provides a pulse signal SRSS2 having one of two patterns to the isolation circuit 153. The isolation circuit 153 provides corresponding isolated pulse signals ISRSS1 and ISRSS2 to the controller 150. The controller 150 in one example controls the secondary circuitry based on one or more of the isolated pulse signals ISRSS1 and ISRSS2 to mitigate third quadrant conduction of switching transistors using timing information from one or both of the pulse signals ISRSS1 and ISRSS2. In one example, the controller 150 determines whether to move the turn on edge for the next cycle (N+1) forward or backward based on the presence or absence of a second pulse in a given one of the isolated pulse signals ISRSS1 and ISRSS2, and the controller 150 sets the on-time of the transistor for the next control cycle based on edges of the given one of the isolated pulse signals ISRSS1 and ISRSS2.

FIG. 16A shows one example of the single output pulse generator 1620 in the power conversion system 1600. The pulse generator 1620 includes the output 1601. The pulse generator 1620 is configured to provide the pulse output signal (labeled SR in FIGS. 16A-16C) at the output 1601 based on detected or measured voltage or current condition of the associated transistor 111. The example of FIG. 16AS includes a sense transistor 1602 (e.g., a sense FET) operatively coupled to the transistor 111. In this example, the pulse generator 1620 has an input 1603 of a comparator 1604 that is coupled to a source of the sense transistor 1602. Another input of the comparator 1604 is coupled to a reference node. An output 1605 of the comparator 1604 provides a zero current detection signal ZC. The comparator 1604 in one implementation includes an offset trim input.

An inverter 1606 has an input coupled to the output 1605 of the comparator 1604. The inverter 1606 inverts the zero current detection signal ZC. The inverter 1606 has an output 1607 coupled to an input of a monostable multivibrator 1608. An output 1609 of the monostable multivibrator 1608 provides a zero-crossing detection signal ZCD to a first input 1611 of an OR gate 1612. A second input 1613 of the OR gate 1612 receives a zero-voltage detection signal ZVD. An output 1614 of the OR gate 1612 is coupled to a first input of a switch circuit 1640 for selectively providing the pulse signal SR having a first pattern (e.g., “Pattern 1”) at the output 1601. The output of the switch circuit 1640 provides the pulse output signal SR to the output 1601 of the pulse generator 1620.

The output 1605 of the comparator 1604 is also coupled to a D input 1615 of a D flip flop 1616 (labeled D FF). A clock input 1617 (CLK) of the flip flop 1616 is coupled to the driver of the driver/transistor device 1610 to receive the transistor switching control input signal, labeled IN in FIG. 16A-16E, which corresponds to a gate source voltage Vgs of the transistor 111. The Q output 1618 of the flip flop 1616 is coupled to the second input 1613 of the OR gate 1612 to provide the zero-voltage detection signal ZVD. A reset input 1619 (labeled R) of the flip flop 1616 is coupled to an output of a first delay circuit 1622 (labeled Dly). The Q output 1618 of the flip flop 1616 is also coupled to an input of the first delay circuit 1622 to reset the Q output 1618 and the ZVD signal after a first delay time of the first delay circuit 1622 (e.g., approximately 150 ns or other suitable time).

The output 1605 of the comparator 1604 is also coupled to a second input 1642 of the switch circuit 1640 for selectively providing the pulse signal SR having a second pattern (e.g., “Pattern 2”) at the output 1601. The switch circuit 1640 has a control input controlled by a switch control signal SW provided at a Q output 1636 of an SR latch or flip flop 1632 to selectively provide the pulse signal SR having the first pattern Pattern 1 or the second pattern Pattern 2. A second delay circuit 1630 has an input 1631 coupled to the output 1609 of the monostable multivibrator 1608 to receive the zero-crossing detection signal ZCD. The output of the second delay circuit 1630 is coupled to a reset input 1634 (labeled R) of the SR latch 1632. The set input 1631 (labeled S) is coupled to the output 1618 of the flip flop 1616.

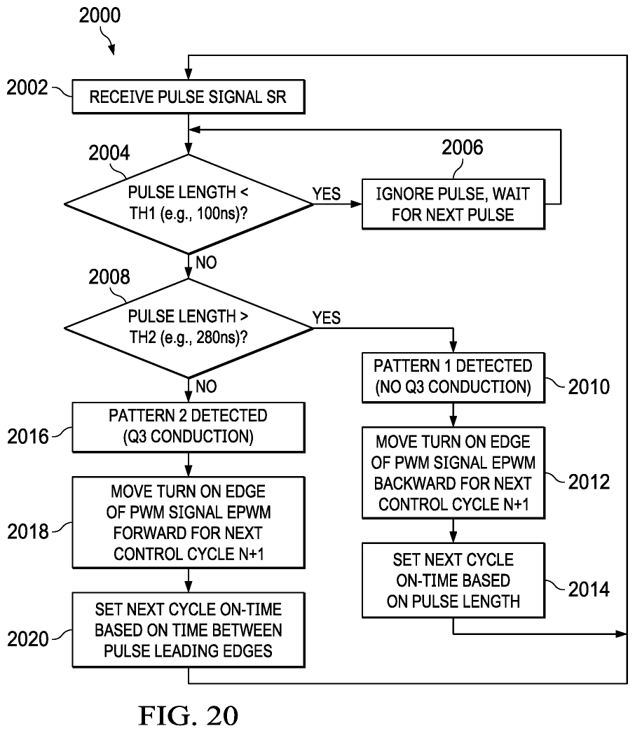

FIGS. 16B and 16C show signals in operation of the pulse generator 1620 in two example control cycles in which the output pulse signal SR of the single output pulse generator 1620 has the respective first and second pulse patterns. FIG. 16B shows a graph 1650 having a curve 1651 that shows the drain-source voltage Vdsₛ₂ of the transistor 111, a curve 1652 of the drain-source current I_{sd2} of the transistor 111, a curve 1653 of the transistor gate-source voltage Vgs (also labeled IN), a curve 1654 showing the zero current detection signal ZC, a curve 1655 showing the zero-voltage detection signal ZVD, a curve 1656 showing the zero-crossing detection signal ZCD, a curve 1657 showing the delayed zero-crossing detection signal at the output 1634 of the second delay circuit 1630 (labeled ZCD Dly in FIG. 16B), a curve 1658 showing the switch control signal SW at the Q output 1636 of the SR latch 1632, and a curve 1659 showing the output pulse signal SR (labeled SR Signal) in FIG. 16B of the pulse generator 1620. In the example of FIG. 16B, the output pulse signal SR (curve 1659) has the first pattern (Pattern 1) with a single pulse with an input pulse time or duration labeled TIPW that represents the on time that will mitigate or avoid third quadrant conduction of the transistor 111 for use by the controller 150 in setting the on time for the next control cycle. The controller 150 determines that the pulse signal SR has a single pulse and detects the first pattern Pattern 1 to move the turn on time for the next control cycle forward, as described further below in connection with FIG. 20.

FIG. 16C shows a graph 1660 illustration operation of the pulse generator 1620 for another control cycle to generate the pulse signal SR having the second pattern Pattern 2. The graph 1660 has a curve 1661 that shows the drain-source voltage Vdsₛ₂ of the transistor 111, a curve 1662 showing the drain-source current I_{sd2} of the transistor 111, a curve 1663 showing the transistor gate-source voltage Vgs (also labeled IN), a curve 1664 showing the zero current detection signal ZC, a curve 1665 showing the zero-voltage detection signal ZVD, a curve 1666 showing the zero-crossing detection signal ZCD, a curve 1667 showing the delayed zero-crossing detection signal at the output 1634 of the second delay circuit 1630 (labeled ZCD Dly in FIG. 16C), a curve 1668 showing the switch control signal SW at the Q output 1636 of the SR latch 1632, and a curve 1669 showing the output pulse signal SR (labeled SR Signal in FIG. 16C) of the pulse generator 1620. In the example of FIG. 16C, the output pulse signal SR (curve 1669) has the second pattern (Pattern 2) with two pulses, and the input pulse time or duration labeled TIPW corresponding to the time between the rising edges of the two pulses in Pattern 2. The time or duration labeled TIPW represents the on time that will mitigate or avoid third quadrant conduction of the transistor 111 for use by the controller 150 in setting the on time for the next control cycle. The controller 150 determines that the pulse signal SR has two pulses, in one example, by determining that the first pulse has a duration less than a threshold and detects the second pattern Pattern 2 to move the turn on time for the next control cycle backward, as described further below in connection with FIG. 20.

FIG. 16D shows a graph 1670 with a curve 1671 that shows the drain-source voltage Vdsₛ₂ of the transistor 111, a curve 1672 showing the drain-source current I_{sd2} of the transistor 111, a curve 1673 showing the transistor gate-source voltage Vgs (also labeled IN(N)) for a current control cycle N of the pulse generator 1620, a curve 1674 showing the output pulse signal SR (labeled SR(N) in FIG. 16B) for the current control cycle N of the pulse generator 1620, a curve 1675 showing the transistor gate-source voltage Vgs (also labeled IN(N+1)) for the next control cycle N of the pulse generator 1620, a curve 1676 showing the output pulse signal SR (labeled SR(N+1) in FIG. 16D) for the next control cycle N of the pulse generator 1620. The curve 1674 shows an example of the second pattern Pattern 2 (also labeled 1677 in FIG. 16D) for the current control cycle N of the pulse generator 1620. The curve 1676 shows an example of the first pattern Pattern 1 (also labeled 1678 in FIG. 16D) for the next control cycle N+1 of the pulse generator 1620.

FIG. 16E shows another example pulse signal having another example second pulse pattern of another implementation of the single output pulse generator 1620 in a present control cycle. A graph 1680 illustration operation of the pulse generator 1620 for another control cycle to generate the pulse signal SR having the second pattern Pattern 2. The graph 1680 has a curve 1681 showing the drain-source voltage Vdsₛ₂ of the transistor 111, a curve 1682 showing the drain-source current I_{sd2} of the transistor 111, a curve 1683 showing the transistor gate-source voltage Vgs (also labeled IN), a curve 1684 showing the zero current detection signal ZC, a curve 1685 showing the zero-voltage detection signal ZVD, a curve 1686 showing the zero-crossing detection signal ZCD, a curve 1687 showing the delayed zero-crossing detection signal ZCD Dly, a curve 1688 showing the switch control signal SW, and a curve 1689 showing another implementation of the output pulse signal SR (labeled SR Signal in FIG. 16C) of the pulse generator 1620. In this example, the controller 150 determines that the pulse signal SR has two pulses and detects the second pattern, Pattern 2, to move the turn on time for the next control cycle backward.

FIG. 17 shows another power conversion system 1700 with pulse timing adjustment by the controller 150 to mitigate third quadrant conduction of switching transistors using timing information from one or more external pulse generators 1620 coupled to a transistor in driver/transistor devices 1710 in a half bridge secondary circuit. The pulse generators 1620 and the controller 150 in this example operate as described above in connection with FIGS. 16-16E and FIG. 20 below.

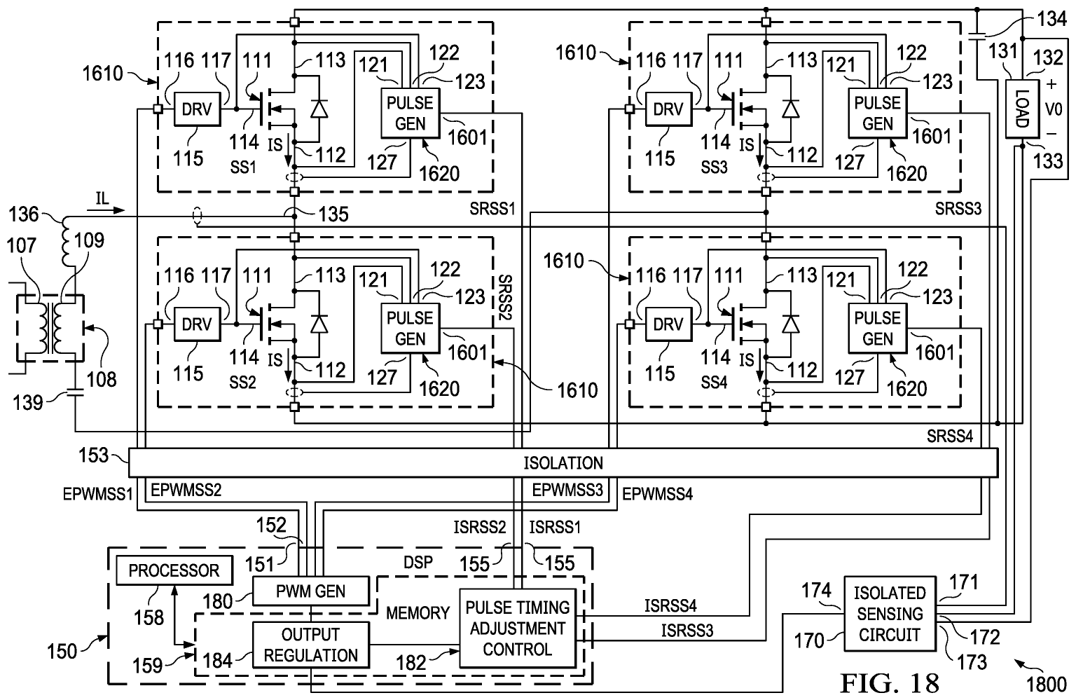

FIG. 18 shows another power conversion system 1800 with pulse timing adjustment by the controller 150 to mitigate third quadrant conduction of switching transistors 111 using timing information from the pulse generators 1620 of FIG. 16A at four corners of a full bridge secondary circuit. The power conversion system 1800 includes similarly numbered components as illustrated and described above in connection with the system 100 of FIGS. 1-1E and the system 1600 of FIG. 16 except as noted herein. In this example, the primary side circuitry (not shown in FIG. 18) is as described above. In addition, the pulse generators 1620 are as described above.

The system 1800 includes a full bridge (e.g., H-bridge) configuration of integrated driver/transistor devices 1610 of the secondary circuit, including a first branch with integrated driver/transistor devices 1610 labeled SS1 and SS2, as well as a second circuit branch with integrated driver/transistor devices 1610 labeled SS3 and SS4. The individual integrated driver/transistor devices 1610 in all four corners of the full bridge include an integrated pulse generator 1620, and only a single pulse output is used from each individual pulse generator 1620. This configuration reduces the number of isolation channels of the isolation circuit 153.

The pulse output 1601 of the pulse generator 120 of the driver/transistor device 1610 of the secondary circuit labeled “SS1” provides a pulse signal SRSS1 to the isolation circuit 153, and the pulse output 1601 of the pulse generator 1620 of the driver/transistor device 1610 of the secondary circuit labeled “SS2” provides the second pulse signal SRSS2 to the isolation circuit 153. In addition, the pulse output 1601 of the pulse generator 1620 of the driver/transistor device 1610 of the secondary circuit labeled “SS3” provides pulse signal SRSS3 to the isolation circuit 153, and the pulse output 1601 of the pulse generator 1620 of the driver/transistor device 1610 of the secondary circuit labeled “SS4” provides the pulse signal SRSS4 to the isolation circuit 153. The isolation circuit 153 provides corresponding isolated pulse signals ISRSS1, ISRSS2, ISRSS3, and ISRSS4 to the controller 150. The controller 150 in one example operates as described above. In the full bridge configuration of FIG. 18, the transistors 111 of the driver/transistor devices 110 labeled SS2 and SS3 conduct together and the transistors 111 of the driver/transistor devices 110 labeled SS1 and SS4 conduct together. The controller 150 in one example operates as described above in connection with FIGS. 16-16E to implement pulse timing adjustment based on one or more of the isolated pulse signals ISRSS1, ISRSS2, ISRSS3, and ISRSS4 to mitigate third quadrant conduction of switching transistors 111 of the full bridge secondary circuit. In one example, the controller 150 determines whether to move the turn on edge for the next cycle (N+1) forward or backward based on the presence or absence of a second pulse in the ISRSS1, ISRSS2, ISRSS3, and ISRSS4 signals, and the controller 150 sets the on-time of the transistor for the next control cycle based on the time between rising edges of the ISRSS1, ISRSS2, ISRSS3, and ISRSS4 pulse signals.

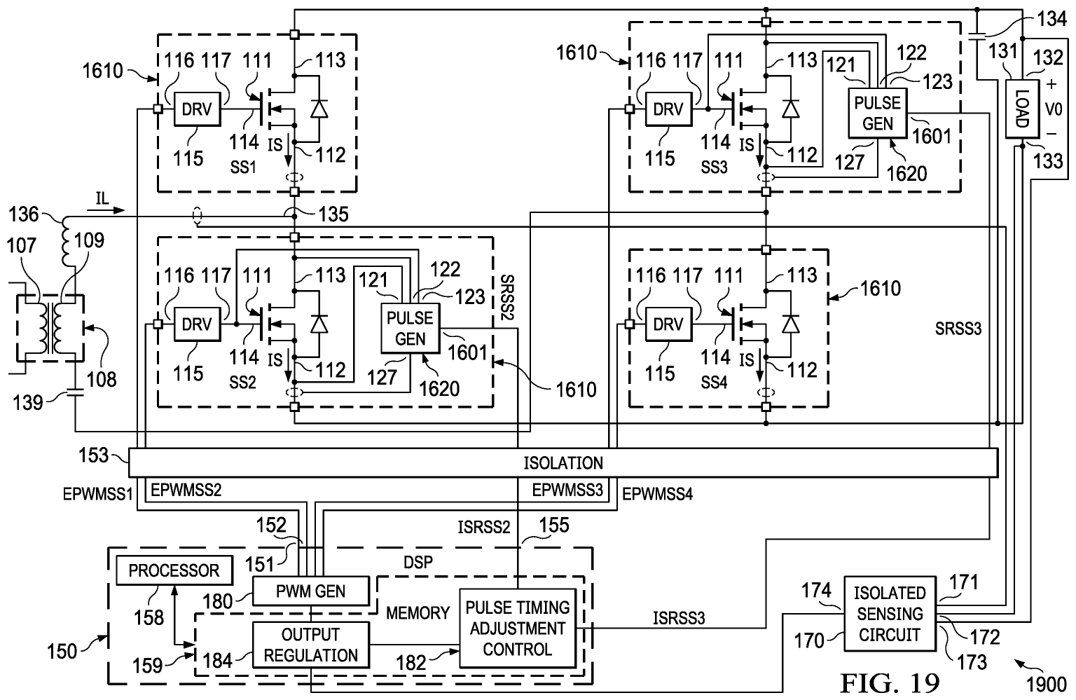

FIG. 19 shows a power conversion system 1900 with pulse timing adjustment by the controller 150 to mitigate third quadrant conduction of switching transistors using timing information from pulse generators 1620 at two corners of a full bridge secondary circuit. The power conversion system 1900 includes similarly numbered components as illustrated and described above in connection with the system 100 of FIGS. 1-1E and FIGS. 16-16E except as noted herein. In this example, the primary side circuitry (not shown in FIG. 19) is as described above. In addition, the pulse generators 1620 are as described above. The system 1900 includes a full bridge (e.g., H-bridge) configuration of integrated driver/transistor devices 1610 of the secondary circuit, including a first branch with integrated driver/transistor devices 1610 labeled SS1 and SS2, as well as a second circuit branch with integrated driver/transistor devices 1610 labeled SS3 and SS4. The individual integrated driver/transistor devices 1610 in two corners of the full bridge, SS2 and SS3 in this example, include an integrated pulse generator 1620. In another example, the individual integrated driver/transistor devices 1610 in the other two corners of the full bridge (e.g., SS1 and SS4) include an integrated pulse generator 1620.

In this example, the pulse generators 1620 are as described above, but only a single pulse output is used from each individual pulse generator 1620. This configuration reduces the number of isolation channels of the isolation circuit 153. The pulse output 1601 of the pulse generator 1620 of the driver/transistor device 1610 of the secondary circuit labeled “SS3” provides a pulse signal SRSS3 to the isolation circuit 153, and the pulse output 1601 of the pulse generator 1620 of the driver/transistor device 1610 of the secondary circuit labeled “SS2” provides the pulse signal SRSS2 to the isolation circuit 153. The isolation circuit 153 provides corresponding isolated pulse signals ISSRS3 and ISSRS2 to the controller 150. The controller 150 in one example operates as described above. In the full bridge configuration of FIG. 19, the transistors 111 of the driver/transistor devices 1610 labeled SS2 and SS3 conduct together and the respective pulse generators 1620 provide the SRSS2 and SRSS3 pulse signals to the controller 150 as the respective isolated pulse signals ISSRS2 and ISSRS3 via the isolation circuit 153. The controller 150 in one example operates as described above to implement pulse timing adjustment based on one or both of the isolated pulse signals ISSRS2 and ISSRS3 to mitigate third quadrant conduction of switching transistors 111 of the full bridge secondary circuit.

FIG. 20 shows a flow diagram 2000 that illustrates one pulse timing adjustment implementation in the controller 150 using the SR signals generated by the pulse generator 1620 of FIG. 16A. The controller 150 receives the pulse signal SR at 2002 and determines at 2004 whether a pulse length of the first analyzed pulse is less than a first threshold TH1 (e.g., 100 ns or something less than the first delay time of the first delay circuit 1622 in FIG. 16A above). If so (YES at 2004), the controller 150 ignores the pulse at 2006 and waits for the next pulse at 2004. This feature allows the controller 150 to start asynchronously and analyze the longer pulse of the SR signal (e.g., to differentiate between the patterns of FIGS. 16B and 16C above). If the analyzed pulse length is greater than or equal to the first threshold TH1 (NO at 2004), the controller 150 determines at 2008 whether the pulse length is greater than a second threshold TH2 (e.g., 280 ns or something greater than the first delay time of the first delay circuit 1622). If so (YES at 2008), the controller 150 detects the first pattern Pattern 1 at 2010, moves the turn on edge of the next control cycle N+1 backward at 2012 and sets the next cycle on time based on the pulse length of the analyzed pulse at 2014. The controller 150 then returns to receive the next pulse at 2002. Otherwise (NO at 2008), the controller 150 detects the second pattern Pattern 2 at 2016, moves the turn on edge of the next control cycle N+1 forward at 2018 and sets the next cycle on time at 2020 based on the time between leading edges of the two pulses of the pulse signal SR. The controller 150 then returns to receive the next pulse at 2002.

The described examples provide synchronous rectification control methods and apparatus that overcomes the gate drive propagation delay. The example controller 150 provides in advance PWM signal to compensate for gate driver delay for a synchronous rectifier switch in the next control cycle, and the delay compensation is completed in a close online tuning loop. In certain implementations, the controller 150 counts the number of switching cycles in which third quadrant conduction occurs, for example, by counting pulses, and the controller 150 selectively adjusts one or both of the PWM signal edges based on measurements of electrical parameters of the transistor 111. Examples include turn on edge control according to the zero-voltage detection signal from a smart gate driver, as well as turn off edge control according to zero-current detection signal and from a smart gate driver. In certain examples, turn on edge control is implemented according to transistor drain-source voltage information with a sensing window. One example, turn off edge control is implemented using a high bandwidth current sensor with zero crossing detection pulse, and PWM pulse width information is provided by a current sensor.

Modifications are possible in the described examples, and other implementations are possible, within the scope of the claims.

What is claimed is:

1. A method, comprising:
generating a pulse width modulated (PWM) signal, the PWM signal having a first edge to turn a transistor on and a second edge to turn the transistor off in respective switching cycles of a power conversion system;
determining a target turn on point based on a measured electrical signal of the transistor responsive to the PWM signal of a switching cycle of a present control cycle;
determining a target turn off point based on the measured electrical signal of the transistor responsive to the PWM signal of the switching cycle of the present control cycle;
based on the determined target turn on point, adjusting the first edge of the PWM signal for a switching cycle of a subsequent control cycle; and
based on the determined target turn off point, adjusting the second edge of the PWM signal for the switching cycle of the subsequent control cycle.

2. The method of claim 1, comprising:
generating a pulse signal that represents third quadrant conduction of the transistor based on the measured electrical signal of the transistor responsive to the PWM signal of the switching cycle of the present control cycle; and
determining the target turn on point based on the pulse signal.

3. The method of claim 2, comprising:
generating a first edge of the pulse signal responsive to a drain-source voltage of the transistor transitioning below a threshold in the switching cycle of the present control cycle; and
generating a second edge of the pulse signal responsive to the drain-source voltage of the transistor transitioning above the threshold in the switching cycle of the present control cycle.

4. The method of claim 3, comprising:
responsive to detecting the first edge of the pulse signal in the switching cycle of the present control cycle, adjusting the first edge of the PWM signal forward for the switching cycle of the subsequent control cycle; and
responsive to not detecting the first edge of the pulse signal in the switching cycle of the present control cycle, adjusting the first edge of the PWM signal backward for the switching cycle of the subsequent control cycle.

5. The method of claim 2, comprising:
responsive to the pulse signal indicating third quadrant conduction of the transistor in the switching cycle of the present control cycle, adjusting the first edge of the PWM signal forward for the switching cycle of the subsequent control cycle; and
responsive to the pulse signal indicating no third quadrant conduction of the transistor in the switching cycle of the present control cycle, adjusting the first edge of the PWM signal backward for the switching cycle of the subsequent control cycle.

6. The method of claim 2, comprising:
generating the PWM signal in each of an integer number M switching cycles of the present control cycle, M being greater than 2;
counting a number of the pulse signals that indicate third quadrant conduction of the transistor in the respective switching cycle of the present control cycle;
responsive to the counted number being greater than a first threshold for the M switching cycles of the present control cycle, adjusting the first edge of the PWM signal forward for the switching cycles of the subsequent control cycle; and
responsive to the counted number being less than a second threshold for the M switching cycles of the present control cycle, adjusting the first edge of the PWM signal backward for the switching cycles of the subsequent control cycle, the first threshold being greater than the second threshold.

7. The method of claim 6, comprising:
generating a first edge of the pulse signal responsive to a drain-source voltage of the transistor transitioning below a threshold in the switching cycle of the present control cycle; and
generating a second edge of the pulse signal responsive to the drain-source voltage of the transistor transitioning above the threshold in the switching cycle of the present control cycle.

8. The method of claim 1, comprising:
responsive to the target turn on point indicating third quadrant conduction of the transistor in the switching cycle of the present control cycle, adjusting the first edge of the PWM signal forward for the switching cycle of the subsequent control cycle; and
responsive to the target turn on point indicating no third quadrant conduction of the transistor in the switching cycle of the present control cycle, adjusting the first edge of the PWM signal backward for the switching cycle of the subsequent control cycle.

9. The method of claim 1, comprising:
generating the PWM signal in each of an integer number M switching cycles of the present control cycle, M being greater than 2;
counting a number of the switching cycles of the present control cycle for which the measured electrical signal indicates third quadrant conduction of the transistor in the respective switching cycle;
responsive to the counted number being greater than a first threshold for the M switching cycles of the present control cycle, adjusting the first edge of the PWM signal forward for the switching cycles of the subsequent control cycle; and
responsive to the counted number being less than a second threshold for the M switching cycles of the present control cycle, adjusting the first edge of the PWM signal backward for the switching cycles of the subsequent control cycle, the first threshold being greater than the second threshold.

10. A non-transitory computer readable medium that stores computer executable instructions, which, when executed by a processor, cause the processor to:
generate a pulse width modulated (PWM) signal, the PWM signal having a first edge to turn a transistor on and a second edge to turn the transistor off in respective switching cycles of a power conversion system;
determine a target turn on point based on a measured electrical signal of the transistor responsive to the PWM signal of a switching cycle of a present control cycle;
determine a target turn off point based on the measured electrical signal of the transistor responsive to the PWM signal of the switching cycle of the present control cycle;
based on the determined target turn on point, adjust the first edge of the PWM signal for a switching cycle of a subsequent control cycle; and
based on the determined target turn off point, adjust the second edge of the PWM signal for the switching cycle of the subsequent control cycle.

11. The non-transitory computer readable medium of claim 10, storing further computer executable instructions, which, when executed by a processor, cause the processor to:
responsive to the target turn on point indicating third quadrant conduction of the transistor in the switching cycle of the present control cycle, adjust the first edge of the PWM signal forward for the switching cycle of the subsequent control cycle; and
responsive to the target turn on point indicating no third quadrant conduction of the transistor in the switching cycle of the present control cycle, adjust the first edge of the PWM signal backward for the switching cycle of the subsequent control cycle.

12. The non-transitory computer readable medium of claim 10, storing further computer executable instructions, which, when executed by a processor, cause the processor to:
generate the PWM signal in each of an integer number M switching cycles of the present control cycle;
count a number of the switching cycles of the present control cycle for which the measured electrical signal indicates third quadrant conduction of the transistor in the respective switching cycle;
responsive to the counted number being greater than a first threshold for the M switching cycles of the present control cycle, adjust the first edge of the PWM signal forward for the switching cycles of the subsequent control cycle; and
responsive to the counted number being less than a second threshold for the M switching cycles of the present control cycle, adjust the first edge of the PWM signal backward for the switching cycles of the subsequent control cycle, the first threshold being greater than the second threshold.

13. A system, comprising:
a transistor; and
a controller configured to:
generate a pulse width modulated (PWM) signal, the PWM signal having a first edge to turn the transistor on and a second edge to turn the transistor off in respective switching cycles;
determine a target turn on point based on a measured electrical signal of the transistor responsive to the PWM signal of a switching cycle of a present control cycle;
determine a target turn off point based on the measured electrical signal of the transistor responsive to the PWM signal of the switching cycle of the present control cycle;
based on the determined target turn on point, adjust the first edge of the PWM signal for a switching cycle of a subsequent control cycle; and
based on the determined target turn off point, adjust the second edge of the PWM signal for the switching cycle of the subsequent control cycle.

14. The system of claim 13, comprising:
a pulse generator having a first input, a second input, and an output, the first input coupled to a source of the transistor, the second input coupled to a drain of the transistor, the pulse generator configured to:
generate a first edge of a pulse signal at the output responsive to a drain-source voltage of the transistor transitioning below a threshold in the switching cycle of the present control cycle, and
generate a second edge of the pulse signal at the output responsive to the drain-source voltage of the transistor transitioning above the threshold in the switching cycle of the present control cycle; and
an isolation circuit coupled to the output, the isolation circuit configured to deliver a signal to the controller based on the pulse signal.

15. The system of claim 13, wherein the controller is configured to:
responsive to the target turn on point indicating third quadrant conduction of the transistor in the switching cycle of the present control cycle, adjust the first edge of the PWM signal forward for the switching cycle of the subsequent control cycle; and
responsive to the target turn on point indicating no third quadrant conduction of the transistor in the switching cycle of the present control cycle, adjust the first edge of the PWM signal backward for the switching cycle of the subsequent control cycle.

16. The system of claim 13, wherein the controller is configured to:
generate the PWM signal in each of an integer number M switching cycles of the present control cycle, =;
count a number of the switching cycles of the present control cycle for which the measured electrical signal indicates third quadrant conduction of the transistor in the respective switching cycle;
responsive to the counted number being greater than a first threshold for the M switching cycles of the present control cycle, adjust the first edge of the PWM signal forward for the switching cycles of the subsequent control cycle; and
responsive to the counted number being less than a second threshold for the M switching cycles of the present control cycle, adjust the first edge of the PWM signal backward for the switching cycles of the subsequent control cycle, the first threshold being greater than the second threshold.

17. An electronic device, comprising a first input; a second input; an output; and a pulse generator; the first input adapted to be coupled to a source of a transistor; the second input adapted to be coupled to a drain of the transistor; and the pulse generator configured to generate a pulse signal at the output responsive to a measured electrical signal of the transistor indicating third quadrant conduction of the transistor.

18. The electronic device of claim 17, wherein the pulse generator is configured to: generate a first edge of the pulse signal at the output responsive to a drain-source voltage of the transistor transitioning below a threshold; and generate a second edge of the pulse signal at the output responsive to the drain-source voltage of the transistor transitioning above the threshold.

19. The electronic device of claim 17, wherein the transistor is integrated into the electronic device.

20. The electronic device of claim 17, further comprising a driver having an output coupled to a gate of the transistor.
